(19) United States
(12) Patent Application Publication
(10) Pub. No.: US 2008/0012081 A1
(43) Pub. Date: Jan. 17, 2008

(54) Semiconductor device and method of manufacturing the same

(75) Inventor: Hiroshi Kudo, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/902,246

(22) Filed: Sep. 20, 2007

Related U.S. Application Data
(63) Continuation of application No. PCT/JP06/05522, filed on Mar. 20, 2006.

(30) Foreign Application Priority Data
Mar. 22, 2005 (JP) 2005-081798

(51) Int. Cl. H01L 29/76

(52) U.S. Cl. 257/408

(57) ABSTRACT

The semiconductor device comprises a plurality of MOS transistors 12 each including a gate electrode 20 formed over a semiconductor substrate 10 with a gate insulating film 18 formed therebetween, and a source diffused layer 28 and a drain diffused layer 34 of a second conductions type arranged with a channel region 36 of a first conduction type therebetween, the source diffused layers 28 and the drain diffused layers 34 of said plural MIS transistors 12 being arranged side by side in the same direction, a pocket region of the first conduction type being formed selectively between the source diffused layer 28 and the channel region 36 of each of the plural MIS transistors 12, and a pocket impurity-not-implanted region being formed between the drain diffused layer 34 and the channel region 36 of each of the plural MIS transistors 12.

### CROSS REFERENCE TO RELATED APPLICATIONS

This application is a Continuation of International Application No. PCT/JP2006/305522, with an international filing date of Mar. 20, 2006, which designating the United States of America, the entire contents of which are incorporated herein by reference. This application is based upon and claims the benefit of priority from the prior Japanese Patent Application No. 2005-081798, filed on Mar. 22, 2005, the entire contents of which are incorporated herein by reference.

### TECHNICAL FIELD

The present invention relates to a semiconductor device and a method of manufacturing the same, more specifically a semiconductor device including a plurality of MIS transistors and a method of manufacturing the same.

### BACKGROUND

Recently, the increasing demand of portable electronic devices rapidly expands the market of the LSI of the portable electronic devices. Most portable electronic devices are driven by batteries and, as operational requirements of the LSI of such portable electronic devices, the LSI is required to decrease the leak current of the electronic devices in stand-by to thereby decrease the electric power consumption thereof in addition to the high-speed operation.

Accordingly, the MOS transistors used in such electronic devices are required to decrease the leak current.

### SUMMARY

The present invention is directed to various embodiments of a semiconductor device and a method for manufacturing the semiconductor device having source diffused layers and drain diffused layers of a plurality of MIS transistors arranged side by side in the same direction, and with the gate electrodes as the mask, an impurity for forming pocket regions is implanted in one direction slanted toward the source sides with respect to the semiconductor substrate surface.

### BRIEF DESCRIPTION OF DRAWINGS

FIG. 1 is a diagrammatic sectional view explaining the leak current of a MOS transistor.

FIG. 2 is a graph of one example of the respective leak current components of the entire leak current of the MOS transistor.

FIG. 3 is diagrammatic sectional views illustrating the pocket ion implantation made obliquely to the substrate surface.

FIG. 4 is a diagrammatic plan view of one example of the layout of a plurality of MOS transistors of the semiconductor device.

FIG. 5 is a diagrammatic sectional view explaining the pocket ion implantation made in the four directions.

FIG. 6 is a diagrammatic plan view showing the layout of a plurality of MOS transistors of the semiconductor device according to a first embodiment of the present invention.

FIG. 7 is a diagrammatic sectional view showing the structure of the MOS transistor of the semiconductor device according to the first embodiment of the present invention.

FIG. 8 is graphs of the leak current and the drive current of the MOS transistors of the semiconductor device according to the first embodiment of the present invention.

FIG. 9 is sectional views showing the method of manufacturing the semiconductor device according to the first embodiment of the present invention (Part 1).

FIG. 10 is sectional views showing the method of manufacturing the semiconductor device according to the first embodiment of the present invention (Part 2).

FIG. 11 is sectional views showing the method of manufacturing the semiconductor device according to the first embodiment of the present invention (Part 3).

FIG. 12 is a block diagram showing the circuit constitution of the semiconductor device according to a second embodiment of the present invention.

FIG. 13 is a circuit diagram showing the equivalent circuit of an SRAM cell of the semiconductor device according to the second embodiment of the present invention.

FIG. 14 is a diagrammatic plan view showing the layout of the SRAM cell of the semiconductor device according to the second embodiment of the present invention.

FIG. 15 is a diagrammatic plan view showing the SRAM cell array of the semiconductor device according to the second embodiment of the present invention.

FIG. 16 is a diagrammatic plan view showing the layout of the conventional SRAM cell.

FIG. 17 is plan views showing the method of manufacturing the semiconductor device according to the second embodiment of the present invention (Part 1).

FIG. 18 is plan views showing the method of manufacturing the semiconductor device according to the second embodiment of the present invention (Part 2).

FIG. 19 is a plan view showing the method of manufacturing the semiconductor device according to the second embodiment of the present invention (Part 3).

FIG. 20 is a diagrammatic plan view showing the SRAM cell array of the semiconductor device according to a modification of the second embodiment of the present invention.

FIG. 21 is a diagrammatic plan view showing the SRAM cell of the semiconductor device according to the modification of the second embodiment of the present invention.

FIG. 22 is a diagrammatic sectional view showing the structure of an NMOS transistor of the semiconductor device according to a third embodiment of the present invention.

FIG. 23 is sectional views showing the method of manufacturing the semiconductor device according to the third embodiment of the present invention.

FIG. 24 is a diagrammatic sectional view showing the structure of a PMOS transistor of the semiconductor device according to a fourth embodiment of the present invention.

FIG. 25 is sectional views showing the method of manufacturing the semiconductor device according to the fourth embodiment of the present invention.

FIG. 26 is graphs of the leak current and the drive current of the MOS transistors of the semiconductor device according to the third and the fourth embodiments of the present invention.

FIG. 27 is a diagrammatic plan view showing the layout of an SRAM cell of the semiconductor device according to a fifth embodiment of the present invention.

FIG. 28 is plan views showing the method of manufacturing the semiconductor device according to the fifth embodiment of the present invention (Part 1).

FIG. 29 is plan views showing the method of manufacturing the semiconductor device according to the fifth embodiment of the present invention (Part 2).

### DETAILED DESCRIPTION OF THE EMBODIMENTS

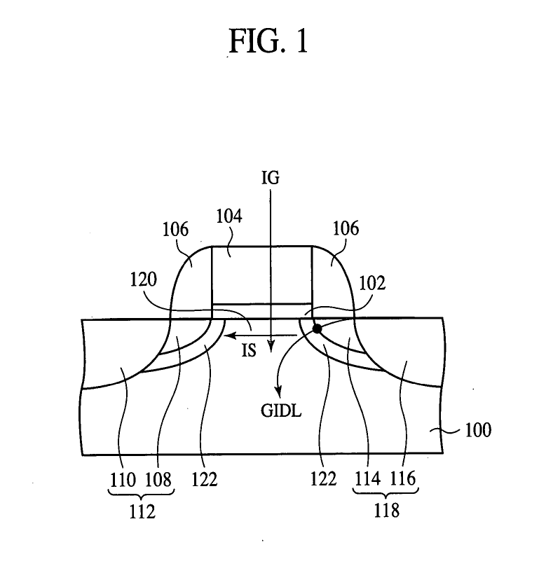

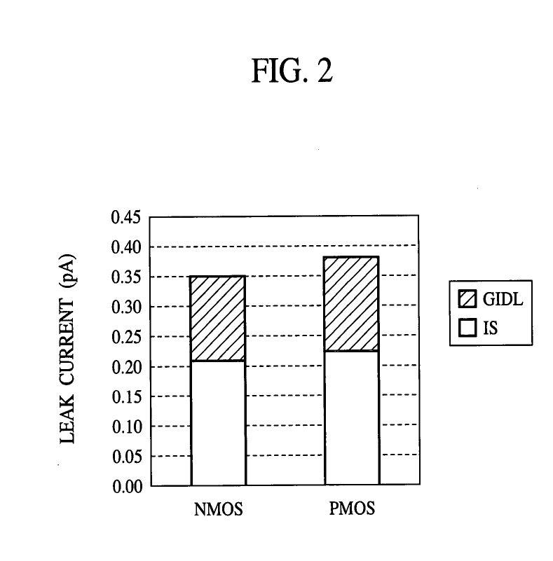

The leak current of the MOS transistor is explained with reference to FIGS. 1 and 2.

FIG. 1 is a diagrammatic sectional view explaining the leak current of a MOS transistor.

As illustrated, on a semiconductor substrate 100 of a first conduction type, a gate electrode 104 is formed with a gate insulating film 102 formed therebetween. A sidewall insulating film 106 is formed on the side walls of the gate electrode 104.

In the semiconductor substrate 100 on the source side of the gate electrode 104, a source diffused layer 112 of a second conduction type is formed of an LDD (Lightly Doped Drain) region 108 formed by self-alignment with the gate electrode 104 and an impurity diffused region 110 formed by self-alignment with the gate electrode 104 and the sidewall insulating film 106. In the semiconductor substrate 100 on the drain side of the gate electrode 104, a drain diffused layer 118 of the second conduction type is formed of an LDD region 114 formed by self-alignment with the gate electrode 104 and an impurity diffused region 116 formed by self-alignment with gate electrode 104 and the sidewall insulating film 106. A channel region 120 is between the source diffused layer 112 and the drain diffused layer 118.

Pocket regions 122 of the first conduction type are respectively formed between the source diffused layer 112 and the channel region 120 and between the drain diffused layer 118 and the channel region 120. When the gate length of the gate electrode 104 is decreased, the threshold voltage of the MOS transistor is lowered, and the operation is made unstable. For the purpose of preventing this, the pocket regions 122 are formed.

In such MOS transistor, as components of the leak current are known the sub-threshold leak (IS) which flows from the drain diffused layer 118 toward the source diffused layer 112, the gate induced drain leakage (GIDL) which flows from the drain diffused layer 118 toward the semiconductor substrate 100, and the gate leak (IG) which flows from the gate electrode 104 toward the semiconductor substrate 100.

The GIDL is generated in the interface between the LDD region 114 and the pocket region 122 at the end of the gate electrode 104 on the drain side. The GIDL increases when the concentrations of impurities implanted in the LDD region 114 and the pocket region 122 are higher.

FIG. 2 is a graph of one example of the respective leak current components of the entire leak current of each of the NMOS transistor and the PMOS transistor.

As evident in the graph, the IS and the GIDL are dominant as the components of the leak current in both the NMOS transistor and the PMOS transistor. In contrast to these, the IG is sufficiently small in comparison with the IS and the GIDL and ignorable as a component of the leak current. For a 0.18 μm node, for example, the IG is smaller by about 2 places than the IS and the GIDL, although varying depending on process technique for the LSI. Accordingly, to decrease the leak current of the MOS transistors, it is important to decrease the IS or the GIDL of the respective components of the leak current.

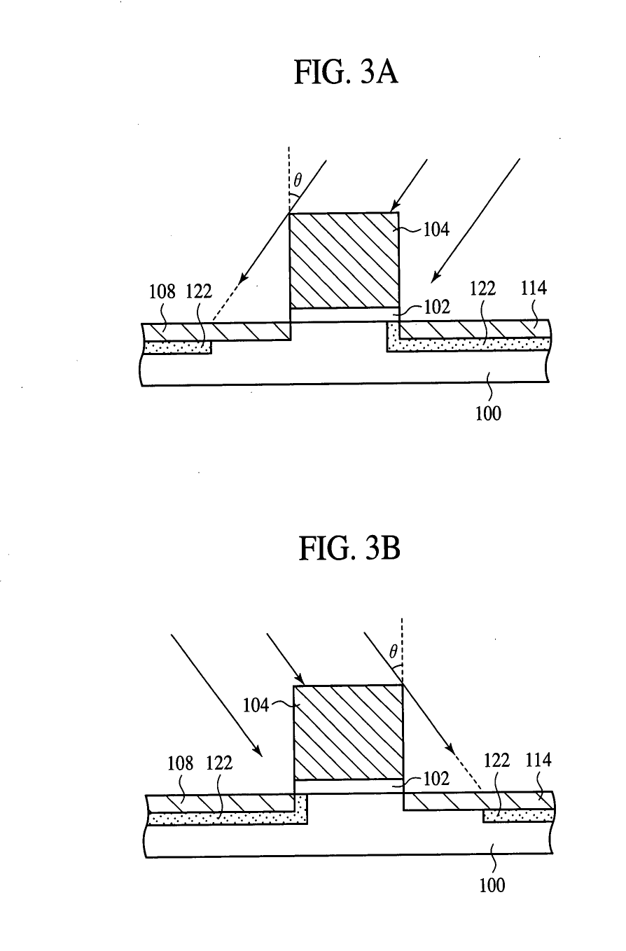

Here, the pocket ion implantation made to form the pocket regions in the semiconductor device will be explained with reference to FIGS. 3 to 5.

FIG. 3 is diagrammatic sectional views illustrating the pocket ion implantation made obliquely to the substrate surface. FIG. 3A illustrates the pocket ion implantation made in one direction slanted toward the drain side with respect to the substrate surface, and FIG. 3B illustrates the pocket ion implantation made in one direction slanted toward the source side with respect to the substrate surface.

As described above, the pocket regions 122 are formed for the end of preventing the operation of the MOS transistor becoming unstable when the gate length of the gate electrode 104 is small. However on the other hand, the pocket ion implantation, which increases the impurity concentration high in these regions, is one cause for increasing the GIDL.

As illustrated in FIG. 3A, when the pocket ion implantation is made in the direction slanted toward the drain side by an angle θ with respect to the semiconductor substrate 100 surface, a region where the impurity is not implanted by the pocket ion implantation is generated on the source side due to the shadow effect of the gate electrode 104. In such case, the IS can be decreased, but the GIDL in the interface between the LDD region 114 and the pocket region 122 on the drain side is increased. Resultantly, it is difficult to generally decrease the leak current.

In contrast to this, as illustrated in FIG. 3B, when the pocket ion implantation is made in the direction slanted toward the source side by the angle θ with respect to the semiconductor substrate 100 surface, a region where the impurity is not implanted by the pocket ion implantation is generated on the drain side due to the shadow effect of the gate electrode 104. Thus, when the pocket ion implantation is made in the direction slated toward the source side, the region where the concentration of the impurity used in the pocket ion implantation is lower is formed in the drain side, which makes it possible to decrease the IS and decrease the GIDL in this region.

The angle θ by which the direction of the pocket ion implantation is slanted toward the source side or the drain side is set in the range of 0°<θ<90°.

In the semiconductor devices, however, due to the layout of a plurality of MOS transistors, the pocket ion implantation is made so that the impurity implanted by the pocket ion implantation becomes uniform among the plural MOS transistors.

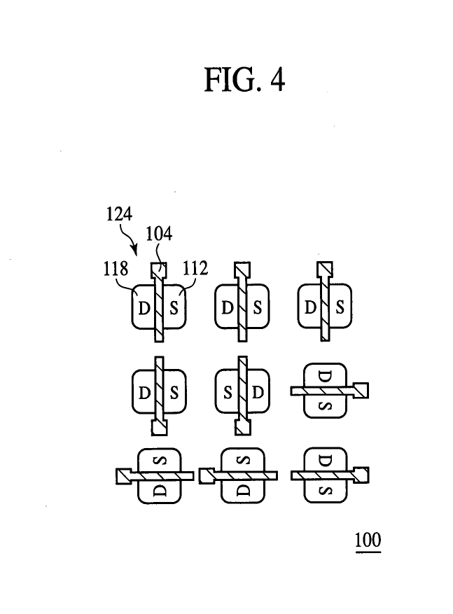

FIG. 4 is a diagrammatic plan view of one example of the layout of a plurality of MOS transistors of the semiconductor device.

Based on the circuit scale, the plural MOS transistors 124 of the semiconductor device are not arranged in a certain direction. Consequently, as illustrated in FIG. 4, the layout direction of the source diffused layers 112 and the drain diffused layers 118 in the semiconductor device 100 variously includes four directions: as viewed in the drawing, from the left to the right, from the right to the left, from the upper to the below, and from the below to the upper.

The ion implantation, as of the pocket ion implantation, etc., is made in a plurality of directions so that impurities can be implanted uniformly in all of the plural MOS transistors.

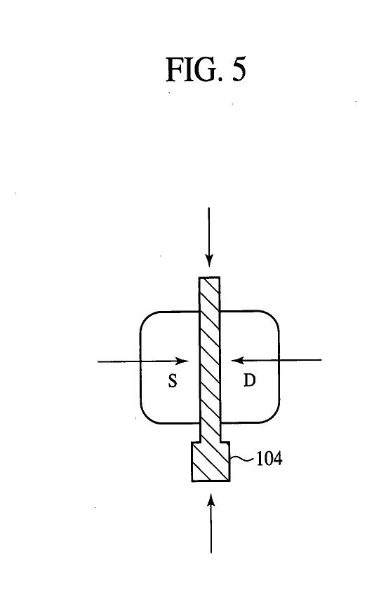

FIG. 5 is a diagrammatic plan view explaining the pocket ion implantation made in the four directions for a plurality of MOS transistors arranged as in FIG. 4.

As indicated by the arrows in the drawing, in the MOS transistors 124, the pocket ion implantation is made in the four directions.

As described above, in the semiconductor device including a plurality of MOS transistors, the layout directions of the source diffused layers and the drain diffused layers are not uniform. Accordingly, it is difficult to make the ion implantation selectively in all the plural MOS transistors from one of the source side and the drain side. When the pocket ion implantation is made in the four directions as illustrated in FIG. 5, the pocket ion implantation is made also from the drain side, which increases the GIDL.

### A First Embodiment

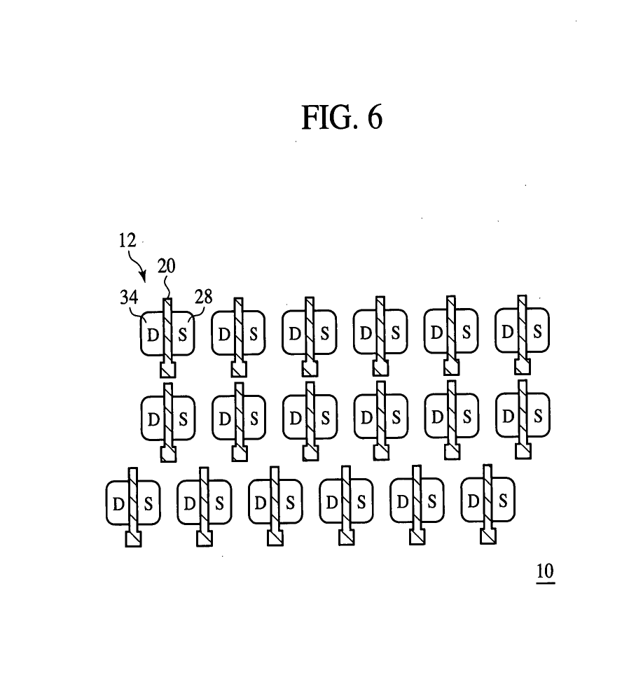

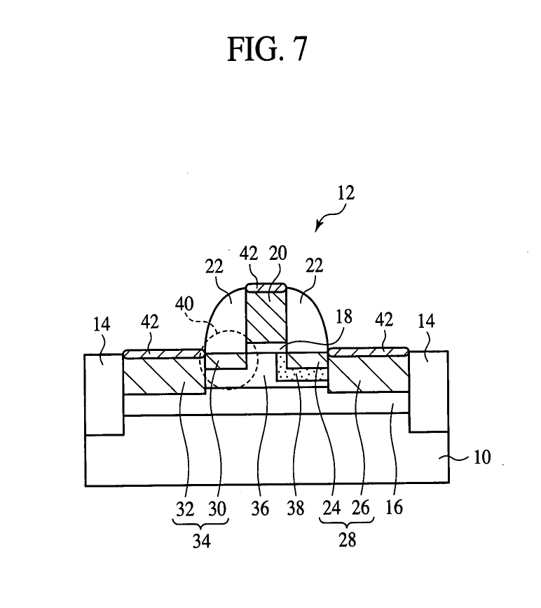

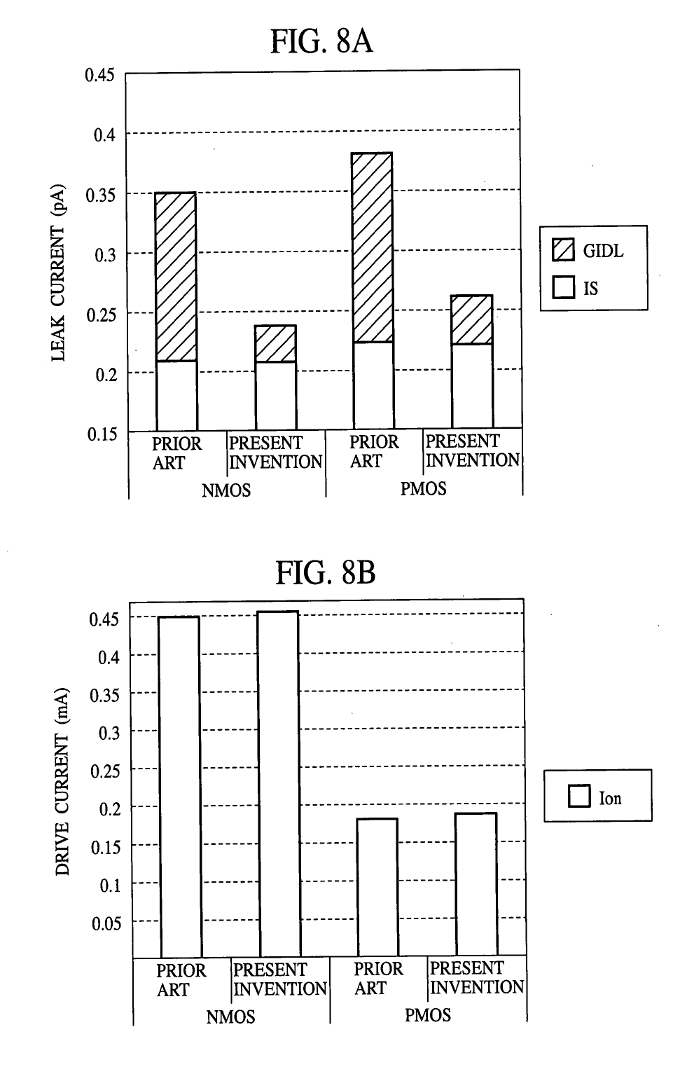

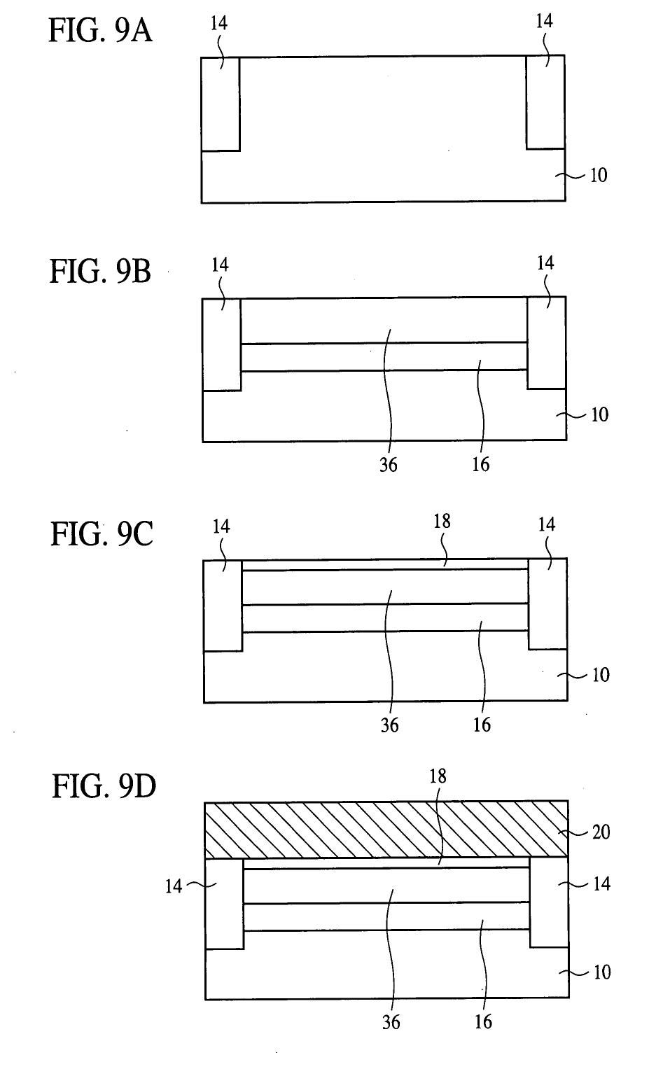

The semiconductor device and the method of manufacturing the same according to a first embodiment of the present invention will be explained with reference to FIGS. 6 to 11. FIG. 6 is a diagrammatic plan view showing the layout of a plurality of MOS transistors of the semiconductor device according to the present embodiment. FIG. 7 is a diagrammatic sectional view showing the structure of the MOS transistor of the semiconductor device according to the present embodiment. FIG. 8 is graphs of the leak current and the drive current of the MOS transistors of the semiconductor device according to the present embodiment. FIGS. 9 to 11 are sectional views showing the method of manufacturing the semiconductor device according to the present embodiment.

First, the structure of the semiconductor device according to the present embodiment will be explained with reference to FIGS. 6 to 8.

In the semiconductor device according to the present embodiment, as illustrated in FIG. 6, a plurality of MOS transistors are formed, arranged over a semiconductor substrate 10. Each MOS transistor 12 includes a gate electrode 20, and a source diffused layer 28 and a drain diffused layer 34 formed in the semiconductor substrate 10 on both sides of the gate electrode 20. In the following plan views, suitably, “S” is indicated in the region where the source diffused layer is formed (including the region for the source diffused layer to be formed in), and “D” is indicated in the region where the drain diffused layer is formed (including the region for the drain diffused layer to be formed in).

The plural MOS transistors 12 include PMOS transistors and NMOS transistors. All the plural MOS transistors 12 may be PMOS transistors or NMOS transistors.

The source diffused layers 28 and the drain diffused layers 34 of the plural MOS transistors 12 are arranged side by side in the same direction.

FIG. 7 illustrates the sectional structure of the MOS transistor 12 arranged as shown in FIG. 6.

In the semiconductor substrate 10, a device isolation film 14 defining an active region is formed.

In the semiconductor substrate 10 with the active region defined, a well 16 of a first conduction type is formed.

On the semiconductor substrate 10, the gate electrode 20 is formed with a gate insulating film 18 formed therebetween. A sidewall insulating film 22 is formed on the side walls of the gate electrode 20.

In the semiconductor substrate 10 on the source side of the gate electrode 20, the source diffused layer 28 of a second conduction type is formed of an LDD region 24 formed by self-alignment with the gate electrode 20, and an impurity diffused region 26 formed by self-alignment with the gate electrode 20 and the sidewall insulating film 22. In the semiconductor substrate 10 on the drain side of the gate electrode 20, the drain diffused layer 34 of the second conduction type is formed of an LDD region 30 formed by self-alignment with the gate electrode 20, and an impurity diffused region 32 formed by self-alignment with the gate electrode 20 and the sidewall insulating film 22. Between the source diffused layer 28 and the drain diffused layer 34 is a channel region 36 of a first conduction type.

A pocket region 38 of the first conduction type is formed between the source diffused layer 28 and the channel region 36. Between the drain diffused layer 34 and the channel region 36, however, no pocket region is formed. That is, between the drain diffused layer 34 and the channel region 36 is a region (pocket impurity-not-implanted region) 40 where the impurity by pocket ion implantation (pocket impurity) is not implanted due to the shadow effect of the gate electrode 20.

Silicide films 42 are formed on the gate electrode 20, the source diffused layer 28 and the drain diffused layer 34.

The semiconductor device according to the present embodiment is characterized mainly in that the source diffused layers 28 and the drain diffused layers 34 of a plurality of MOS transistors 12 are arranged side by side in the same direction, the pocket region 38 is formed selectively between the source diffused layer 28 and the channel region 36 of each MOS transistor 12, and between the drain diffused layer 34 and the channel region 36 is the pocket impurity not implanted region 40.

The source diffused layers 28 and the drain diffused layers 34 of a plurality of MOS transistors 12 are arranged side by side in the same direction, which permits the pocket ion implantation be made in one direction slanted toward the source side for the respective MOS transistors 12. Thus, the pocket region 38 is formed selectively between the source diffused layer 28 and the channel region 36 of each MOS transistor 12, and the pocket impurity not-implanted-region 40 can be formed between the drain diffused layer 34 and the channel region 36 of each MOS transistor 12. Accordingly, the GIDL of all the plural MOS transistors 12 can be decreased, and the electric power consumption of the semiconductor device in stand-by can be decreased.

FIG. 8A is a graph of the leak current of the MOS transistors of the semiconductor device according to the present embodiment, and FIG. 8B is a graph of the drive current. FIGS. 8A and 8B respectively also show the leak current and the drive current of the MOS transistors subjected to the pocket ion implantation in the four directions by the prior art.

As evident in the graph of FIG. 8A, for both the NMOS transistor and the PMOS transistor, the prior art and the present embodiment do not much differ in the IS of the components of the leak current. On the other hand, the GIDL of the present embodiment is decreased down to about ¼ the GIDL of the prior art. Thus, the present embodiment decreases the leak current as a whole down to about a half of the leak current of the prior art.

As evident in the graph of FIG. 8B, for both the NMOS transistor and the PMOS transistor, the present embodiment and the prior art are substantially the same in the drive current. Based on this, it is found that in the present embodiment, the operational characteristics of the MOS transistors are not deteriorated.

As described above, according to the present embodiment, the leak current of the MOS transistors can be decreased without deteriorating the operational characteristics of the MOS transistors.

Next, the method of manufacturing the semiconductor device according to the present embodiment will be explained with reference to FIGS. 9 to 11.

First, in the semiconductor substrate 10 of, e.g., silicon, the device isolation film 14 is formed by, e.g., STI (Shallow Trench Isolation) method to define active regions where a plurality of MOS transistors 12 are to be formed (FIG. 9A). The active regions are defined so that the regions for the source diffused layers 28 of the plural MOS transistors 12 to be formed in and the regions for the drain diffused layers 34 of the plural MOS transistors 12 to be formed in are arranged side by side in the same direction.

Next, an impurity is implanted into the semiconductor substrate 10 by, e.g., ion implantation to form the well 16 of a prescribed conduction type. Into the region where PMOS transistor is to be formed in, phosphorus (P), for example, as an n-type impurity is ion-implanted under conditions, e.g., of a 500 keV acceleration energy and a 1×10¹³ cm⁻² dose. As the n-type impurity, antimony (Sb), arsenic (As) or others may be used. Into the region where the NMOS transistor is to be formed, boron (B), for example, as a p-type impurity is implanted under conditions, e.g., of a 250 keV acceleration energy and a 1×10¹³ cm⁻² dose. As the p-type impurity, iridium (In) or others etc. may be used.

In the ion implantation of the impurity for forming the well 16, a photoresist film prepared by lithography is used as the mask to implant the impurities respectively into the region where the PMOS transistor is to be formed in and the region where the NMOS transistor is to be formed in. This is the same with the ion implantations which will be made later.

Then, an impurity of a prescribed conduction type is implanted into the channel region 36 in the semiconductor substrate 10 by, e.g., ion implantation (FIG. 9B). Into the region where the PMOS transistor is to be formed in, arsenic, for example, as an n-type impurity is implanted under conditions, e.g., of an 80 keV acceleration energy and a 2×10¹² cm⁻² dose. As the n-type impurity, phosphorus, antimony or others may be used. Into the region where the NMOS transistor is to be formed in, boron, for example, as a p-type impurity is implanted under conditions, e.g., of a 20 keV acceleration energy and a 5×10¹² cm⁻² dose. As the p-type impurity, indium or others may be used.

Then, on the semiconductor substrate 10, the gate insulating film 18 of, e.g., a 3 nm-thickness silicon oxide film is formed by, e.g., thermal oxidation (FIG. 9C). As the gate insulating film, hafnium oxide (HfO) film, hafnium aluminum oxide (HfAlO) film, aluminum oxide (AlO) film or any one of these films with nitrogen (N) added may be formed.

Next, a 200 nm-thickness polysilicon film 20, for example, is formed by, e.g., thermal CVD (Chemical Vapor Deposition) method (FIG. 9D).

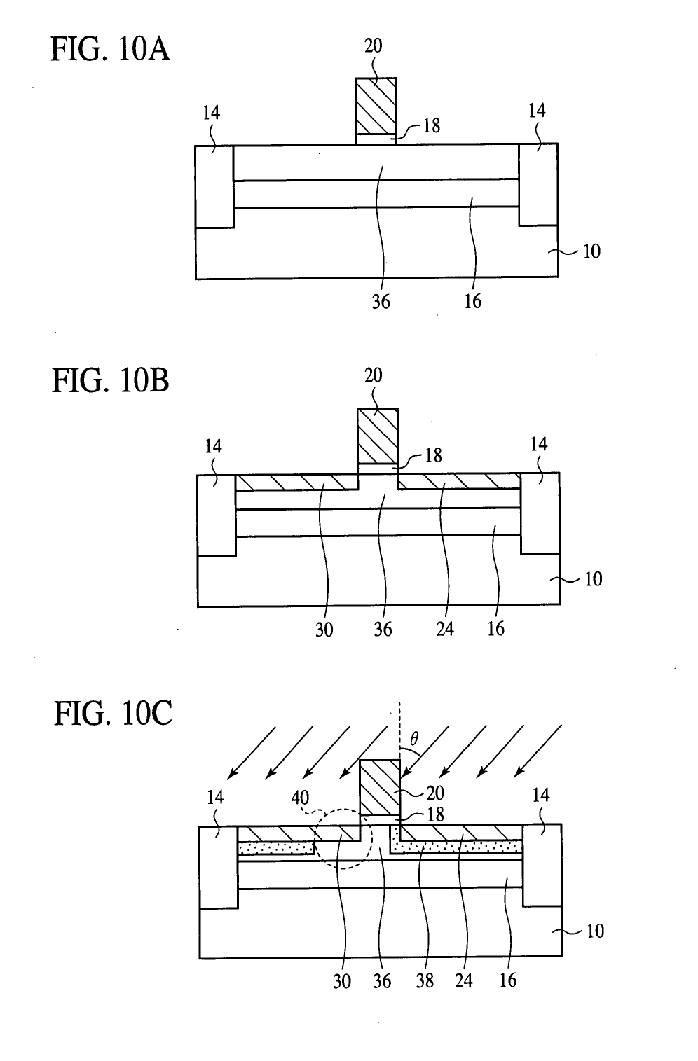

Then, by lithography and etching, the polysilicon film 20 is patterned to form the gate electrode 20 of the polysilicon film having, e.g., a 200 nm-gate length (FIG. 10A). The gate electrode 20 may be formed of a metal or a material containing the metal, such as aluminum (Al), titanium (Ti), titanium nitride (TiN), tungsten (W), nickel silicide (NiSi), cobalt silicide (CoSi) or others.

Then, with the gate electrode 20 as the mask, an impurity is implanted in the semiconductor substrate 10 on both sides of the gate electrode 20. Thus, the LDD regions 24, 30 are formed in the semiconductor substrate 10 on the source side and the drain side of the gate electrode 20 (FIG. 10B). Into the region where the PMOS transistor is to be formed in, boron (B), for example, as a p-type impurity is ion-implanted under conditions, e.g., of a 20 keV acceleration energy and a 2×10¹⁴ cm⁻² dose. Into the region where the NMOS transistor is to be formed in, arsenic, for example, as an n-type impurity is implanted under conditions, e.g., of 20 keV acceleration energy and a 2×10¹⁴ cm⁻² dose. The ion implantation for forming the LDD regions may be made in one direction slanted toward the source side or the drain side with respect to the semiconductor substrate 10 surface.

Then, with the gate electrode 20 as the mask, the pocket ion implantation is made in one direction slanted toward the source side with respect to the semiconductor substrate 10 surface to form the pocket region 38 (FIG. 10C). Into the region where the PMOS transistor is to be formed in, phosphorus, for example, as an n-type impurity is ion-implanted at an incidence angle which is slanted toward the source side by, e.g., 45° under conditions, e.g., of a 30 keV acceleration energy and a 3×13 cm⁻² dose. Into the region where the NMOS transistor is to be formed in, boron, for example, as a p-type impurity is ion-implanted at an incidence angle which is slanted toward the source side by, e.g., 45° under conditions, e.g., of a 20 keV acceleration energy and a 3×10¹³ cm⁻³ dose.

The pocket ion implantation is made in one direction slated toward the source side with respect to the semiconductor substrate 10 surface, whereby between the drain diffused layer 34 and the channel region 36 is the pocket impurity-not-implanted-region 40 due to the shadow effect of the gate electrode 20. Thus, the pocket region 38 are formed selectively between the source diffused layer 28 and the channel region 36.

In the present embodiment, the source diffused layers 28 and the drain diffused layers 34 of a plurality of MOS transistors 12 are arranged side by side in the same direction, which allows the pocket ion implantation to be made in one direction slanted toward the source side for the respective plural MOS transistors 12. Thus, the pocket region 38 is formed selectively between the source diffused layer 28 and the channel region 36 of each MOS transistor 12, and the pocket impurity not-implanted-region 40 can be formed between the drain diffused layer 34 and the channel region 36 of each MOS transistor 12. Accordingly, the GIDL of all the plural MOS transistors 12 can be decreased, and the electric power consumption of the semiconductor device in stand-by can be decreased.

The incidence angle θ for the pocket ion implantation can be suitably set in the range of 0°<θ<90°, depending on a height of the gate electrode 20, etc.

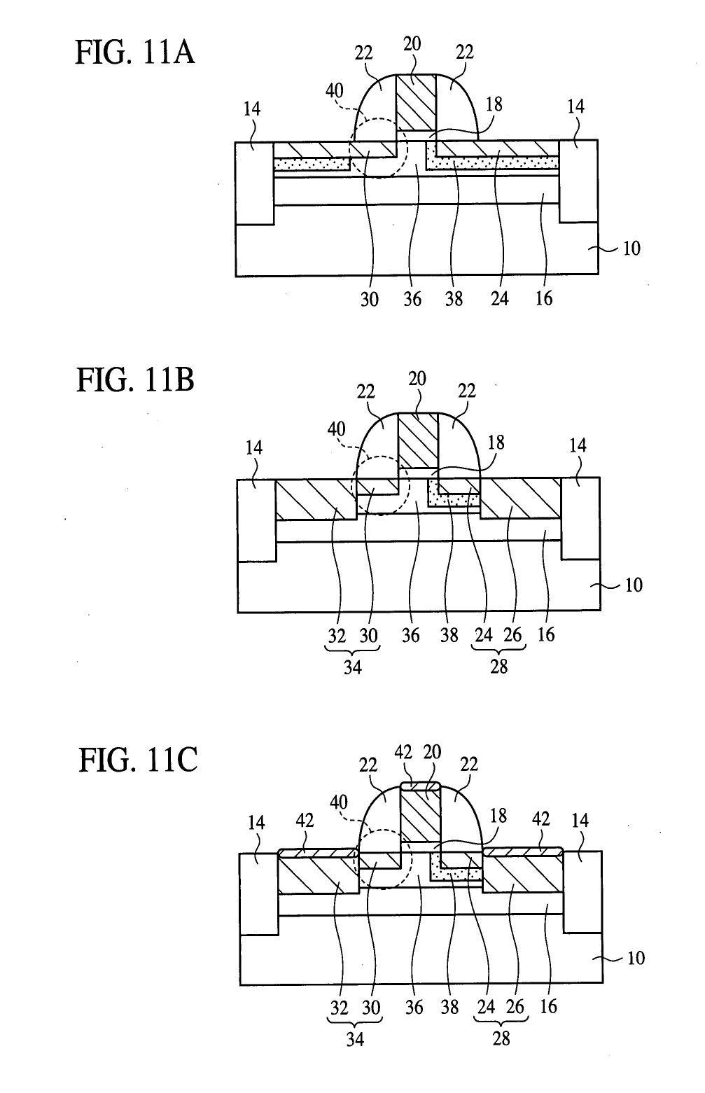

Then, a 2 nm-thickness silicon oxide film, for example, is formed on the entire surface by, e.g., thermal CVD method and is anisotropically etched to form the sidewall insulating film 22 on the side walls of the gate electrode 20 (FIG. 11A).

Next, with the gate electrode 20 and the sidewall insulating film 22 as the mask, an impurity is implanted by, e.g., ion implantation into the semiconductor substrate 10 on both sides of the gate electrode 20 and the sidewall insulating film 22. Thus, the impurity diffused regions 26, 32 are formed in the semiconductor substrate 10 on the source side and the drain side of the gate electrode 20 and the sidewall insulating film 22 (FIG. 11B). Into the region where the PMOS transistor is to be formed in, boron, for example, as a p-type impurity is ion-implanted under conditions, e.g., of a 15 keV acceleration energy and a 1×10¹⁵ cm⁻² dose. Into the region where the NMOS transistor is to be formed in, arsenic, for example as an n-type impurity is ion-implanted under conditions, e.g., of a 20 keV acceleration energy and a 1×10¹⁵ cm⁻² dose.

Thus, the source diffused layer 28 formed of the LDD region 24 and the impurity diffused region 26 is formed in the semiconductor substrate 10 on the source side of the gate electrode 20, and the drain diffused layer 34 formed of the LDD region 30 and the impurity diffused region 32 is formed in the semiconductor substrate 10 on the drain side of the gate electrode 20. The pocket region 38 is formed between the source diffused layer 28 and the channel region 36, but between the drain diffused layer 34 and the channel region 36 is the pocket impurity-not-implanted regions 40.

Next, by the usual salicide process, for example, the silicide films 42 formed of, e.g., cobalt silicide (CoSi) are formed on the gate electrode 20, the source diffused layer 28 and the drain diffused layer 34 (FIG. 11C).

Hereafter, on the semiconductor substrate 10 with the MOS transistor 12 formed on, interconnection layers are suitably formed by the usual semiconductor device manufacturing process.

Thus, the semiconductor device according to the present embodiment is manufactured.

As described above, according to the present embodiment, the source diffused layers 28 and the drain diffused layer 34 of a plurality of MOS transistors 12 are arranged side by side in the same direction, and the pocket ion implantation is made in one direction slanted toward the source side with respect to the semiconductor substrate 10 surface, whereby the pocket region 38 can be formed between the source diffused layer 28 and the channel region 36, while between the drain diffused layer 34 and the channel region 36 can be the pocket impurity-not-implanted regions 40, for the plurality of MOS transistors 12. Thus, the GIDL can be decreased, and the electric power consumption of the semiconductor device in stand-by can be decreased.

In the above, both in the NMOS transistor and the PMOS transistor, the pocket ion implantation is made in one direction slanted toward the source side, but the pocket ion implantation may be made in one direction slanted toward the source side in either of the NMOS transistor and the PMOS transistor.

### A Second Embodiment

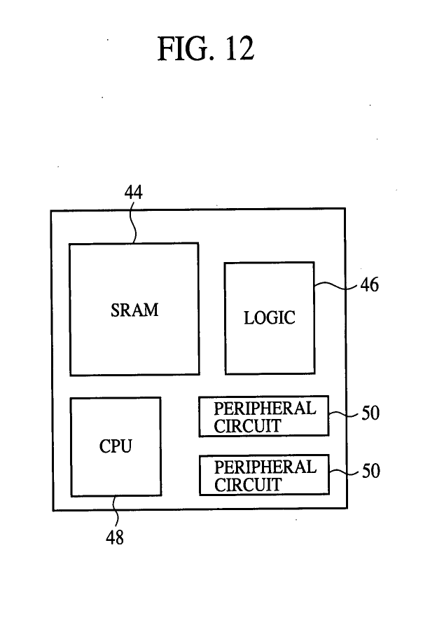

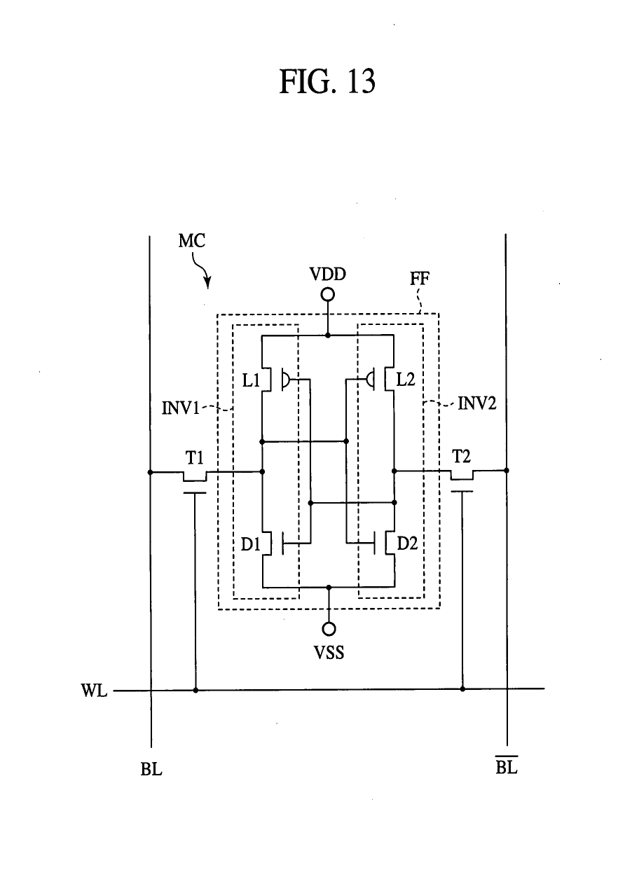

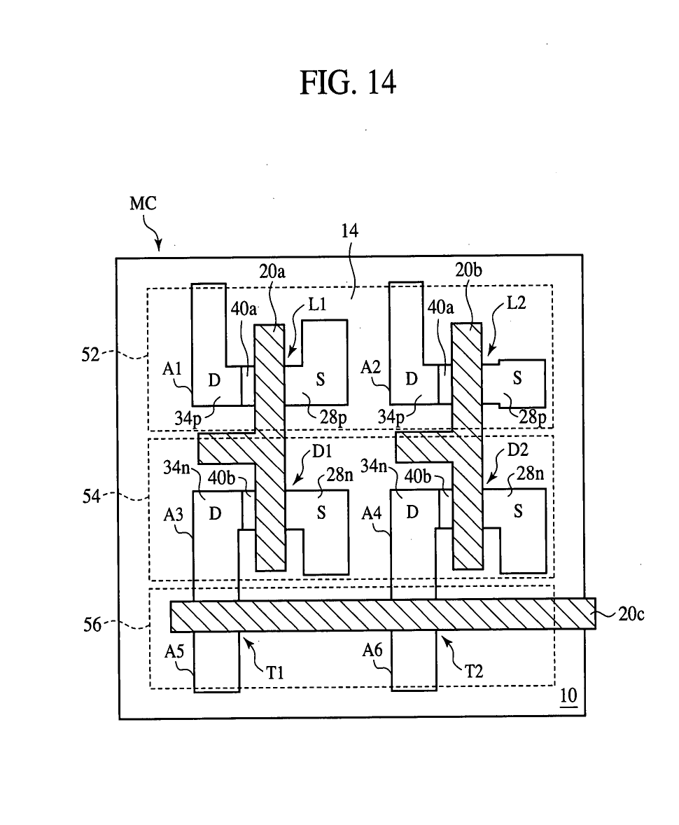

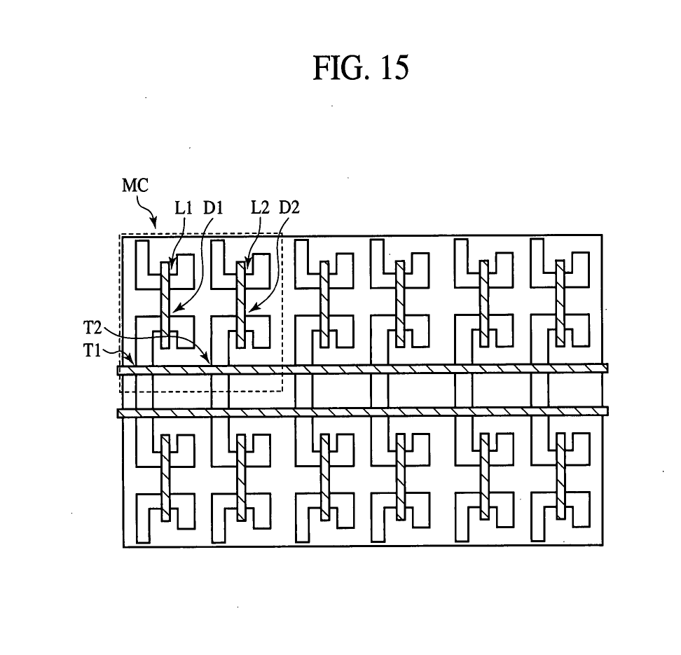

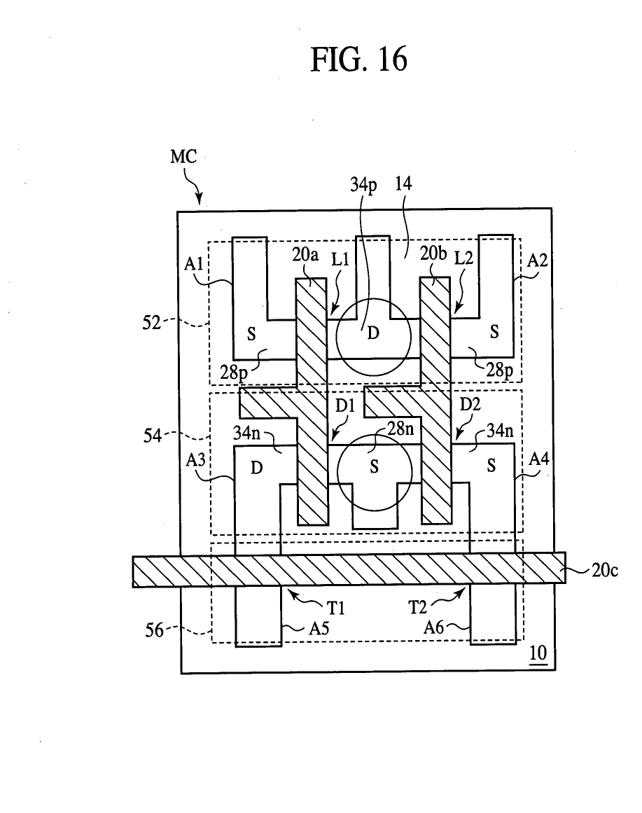

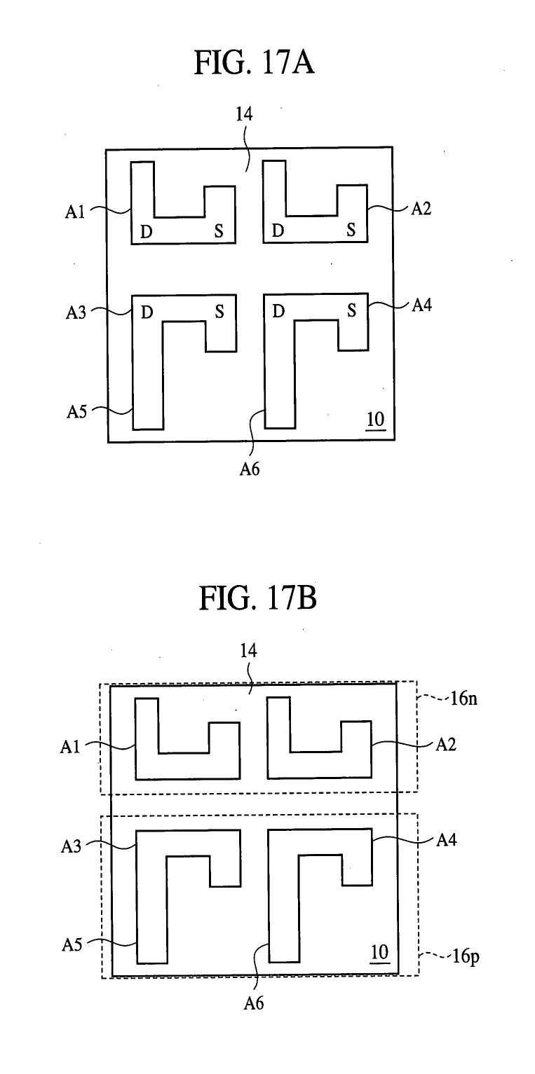

The semiconductor device and the method of manufacturing the same according to a second embodiment of the present invention will be explained with reference to FIGS. 12 to 19. FIG. 12 is a block diagram showing the circuit constitution of the semiconductor device according to the present embodiment. FIG. 13 is a circuit diagram showing the equivalent circuit of an SRAM cell of the semiconductor device according to the present embodiment. FIG. 14 is a diagrammatic plan view showing the layout of the SRAM cell of the semiconductor device according to the present embodiment. FIG. 15 is a diagrammatic plan view showing the SRAM cell array of the semiconductor device according to the present embodiment. FIG. 16 is a diagrammatic plan view showing the layout of the conventional SRAM cell. FIGS. 17 to 19 are plan views showing the method of manufacturing the semiconductor device according to the present embodiment. The same members of the present embodiment as those of the semiconductor device and the method of manufacturing the same according to the first embodiment are represented by the same reference numbers not to repeat or to simplify their explanation.

First, the structure of the semiconductor device according to the present embodiment will be explained with reference to FIGS. 12 to 16.

In the present embodiment, as illustrated in FIG. 12, the semiconductor device comprises an SRAM circuit block 44, a logic circuit block 46, a CPU circuit block 48 and a peripheral circuit block 50, and the present invention is applied to the SRAM circuit block 44. That is, in the present embodiment, the load transistors and the driver transistors forming an SRAM cell of the SRAM circuit block 44 have the source diffused layers and the drain diffused layers arranged side by side in the same direction, and with the gate electrodes as the masks, the pocket ion implantation is made in one direction slanted toward the source sides with respect the substrate surface.

As illustrated in FIG. 13, each SRAM cell MC of the semiconductor device according to the present embodiment is positioned in the intersection region defined by a word line WL and a pair of bit lines BL, /BL (BL bar) intersecting the word line WL. The SRAM cell MC is of CMOS type and includes a pair of load transistors L1, L2, a pair of driver transistors D1, D2 and a pair of transfer transistors T1, T2. The load transistors L1, L2 are PMOS transistors, and the driver transistors D1, D2 and the transfer transistors T1, T2 are NMOS transistors. The SRAM cell includes six MOS transistors.

The load transistor L1 and the driver transistor D1 form an inverter INV1. The load transistor L2 and the driver transistor D2 form an inverter INV2. The inverter INV1 and the inverter INV2 form a flip-flop circuit FF. The flip-flop circuit FF is controlled by the transfer transistors T1, T2 connected to the bit lines BL, /BL and the word line WL.

As illustrated in FIG. 14, each SRAM cell formed on a semiconductor substrate 10 comprises a load transistor part 52 including the load transistors L1, L2, a driver transistor part 54 including the driver transistors D1, D2, and a transfer transistor part 56 including the transfer transistors T1, T2.

In the load transistor part 52, the active region A1 where the load transistor L1 is formed, and the active region A2 where the load transistor L2 is formed are isolated from each other by a device isolation film 14. Thus, the neighboring load transistors L1, L2 are formed independent of each other, and the source diffused layers 28p and the drain diffused layers 34p of the load transistors L1, L2 are arranged side by side in the same direction. In the load transistors L1, L2, pocket regions are formed selectively between the source diffused layers 28p and the channel regions, and between the drain diffused layers 34p and the channel regions are pocket impurity-not-implanted regions 40a.

In the driver transistor part 54, the active region A3 where the driver transistor D1 is formed and the active region A4 where the driver transistor D2 is formed are isolated from each other by the device isolation film 14. Thus, the neighboring driver transistors D1, D2 are formed independent of each other, and the source diffused layers 28n and the drain diffused layers 34n of the driver transistors D1, D2 are arranged side by side in the same direction. In the driver transistors D1, D2, pocket regions are formed selectively between the source diffused layers 28n and the channel regions, and between the drain diffused layers 34n and the channel regions are pocket impurity-not-implanted regions 40b.

In the transfer transistor part 56, the active region A5 where the transfer transistor T1 is formed is connected to the active region A3 where the driver transistor D1 is formed. The active region A6 where the transfer transistor T2 is formed is connected to the active region A4 where the driver transistor D2.

The load transistor L1 and the driver transistor D2 have a common gate electrode 20a. The load transistor L2 and the driver transistor D2 have a common gate electrode 20b. The transfer transistors T1, T2 have a common gate electrode 20c.

The SRAM cell MC illustrated in FIG. 14 described above is repeatedly arranged row-wise (transversely as viewed in the drawing) and column-wise (vertically as viewed in the drawing) as shown FIG. 15, forming a memory cell array.

The SRAM cells MC neighboring row-wise have the load transistors L1, L2, the driver transistors D1, D2 and the transfer transistors T1, T2 arranged in the same direction. The transfer transistors T1, T2 of a plurality of the SRAM cells MC arranged row-wise have a common gate electrode 20c.

A pair of the SRAM cells MC neighboring column-wise have the load transistors L1, L2, the driver transistors D1, D2 and the transfer transistors T1, T2 arranged line symmetrical with each other with respect to the border line between both as a symmetry axis. A pair of the SRAM cells MC neighboring column-wise have the active regions A5 where the transfer transistors T1 are formed connected to each other and have the active regions A6 where the transfer transistors T2 are formed connected to each other.

The semiconductor device according to the present embodiment is characterized mainly in that in each SRAM cell, the neighboring load transistors L1, L2 are formed independent of each other and have the source diffused layers 28p and the drain diffused layers 34p arranged side by side in the same direction, and the neighboring driver transistors D1, D2 are formed independent of each other and have the source diffused layers 28n and the drain diffused layers 34n arranged side by side in the same direction.

In the conventional SRAM cell, the neighboring MOS transistors have the layout in which the neighboring MOS transistors have a source diffused layer or a drain diffused layer in common. FIG. 16 is a diagrammatic plan view showing the layout of the conventional SRAM cell.

As illustrated in the conventional SRAM cell, the active regions A1, A2 are formed integral with each other, and the neighboring load transistors L1, L2 have the drain diffused layer 34p in common. The active regions A3, A4 are formed integral with each other, and the neighboring driver transistors D1, D2 have the source diffused layer 28n in common. That is, the source diffused layers 28p and the drain diffused layers 34p of the load transistors L1, L2 are not arranged side by side in the same direction, and the source diffused layers 28n and the drain diffused layers 34n of the driver transistors D1, D2 are not arranged side by side in the same direction.

Accordingly, the layout of the conventional SRAM cell makes it very difficult to make the pocket ion implantation to be made in one direction slanted toward the source side in the load transistors L1, L2 and the driver transistors D1, D2. Accordingly, it is difficult to decrease the GIDL and decrease the electric power consumption of the semiconductor device in stand-by.

In contrast to the conventional SRAM cell, in the SRAM cell MC of the semiconductor device according to the present embodiment, the neighboring load transistors L1, L2 are formed independent of each other and have the source diffused layers 28p and the drain diffused layers 34p arranged side by side in the same direction, and the neighboring driver transistors D1, D2 are formed independent of each other and have the source diffused layers 28n and the drain diffused layers 34n arranged side by side in the same direction.

Accordingly, in the load transistors L1, L2, the pocket ion implantation can be made in one direction slanted toward the source side with respect to the semiconductor substrate 10 surface. Consequently, in the semiconductor device according to the present embodiment, in both of the load transistors L1, L2, the pocket regions are formed selectively between the source diffused layers 28p and the channel regions, and between the drain diffused layer 34p and the channel regions are the pocket impurity-not-implanted regions 40a as illustrated in FIG. 14.

In the driver transistors D1, D2 as well, the pocket ion implantation can be made in one direction slanted toward the source side with respect to the semiconductor substrate 10 surface. Consequently, in the semiconductor device according to the present embodiment, in both of the driver transistors D1, D2, the pocket regions are formed selectively between the source diffused layers 28n and the channel regions, and between the drain diffused layer 34n and the channel regions are the pocket impurity-not-implanted regions 40b as illustrated in FIG. 14.

As described above, in the load transistors L1, L2 and the driver transistors D1, D2, the pocket ion implantation can be made in one direction slanted toward source side with respect to the semiconductor substrate 10 surface, whereby the GIDL can be decreased, and the electric power consumption of the semiconductor device in stand-by can be decreased.

Next, the method of manufacturing the semiconductor device according to the present embodiment will be explained with reference to FIGS. 17 to 19. In the present embodiment, the method of manufacturing the semiconductor device according to the first embodiment is used to form the load transistors L1, L2 and the driver transistors D1, D2, etc.

First, in the same way as in the step shown in FIG. 9A, the device isolation film 14 is formed in the semiconductor substrate 10 of, e.g., silicon by, e.g., STI method to define the active regions A1-A6 where the load transistors L1, L2, the driver transistors D1, D2 and the transfer transistors T1, T2 are formed (FIG. 17A). The active regions A1-A4 are defined so that the regions where the source diffused layers 28p, 28n of the load transistors L1, L2 and the driver transistors D1, D2 are to be formed and the regions where the drain diffused layers 34p, 34n of the load transistors L1, L2 and the driver transistors D1, D2 are to be formed are arranged side by side in the same direction.

Next, in the same way as in the step shown in FIG. 9B, the well implantation and the channel implantation are sequentially made.

That is, first, impurities are implanted into the semiconductor substrate 10 by, e.g., ion implantation to form the wells 16n, 16p of prescribed conduction types (FIG. 17B). The n-type well 16n is formed in the region where PMOS transistors are to be formed, i.e., in the region where the load transistors L1, L2 are to be formed. The p-type well 16p is formed in the region where NMOS transistors are to be formed, i.e., in the region where the driver transistors D1, D2 and the transfer transistors T1, T2 are to be formed.

Next, impurities of prescribed conduction types are implanted in the channel regions of the semiconductor substrate 10 by, e.g., ion implantation (FIG. 9B). Into the region where the PMOS transistors are to be formed, i.e., into the region where the load transistors L1, L2 are to be formed, an n-type impurity is ion-implanted. Into the region where the NMOS transistors are to be formed, i.e., into the region where the driver transistors D1, D2 and the transfer transistor T1, T2 are to be formed, a p-type impurity is implanted.

With a photoresist film prepared by lithography as the mask, the well implantation and the channel implantation are made respectively into the region where the PMOS transistors are to be formed and into the region where the NMOS transistors are to be formed.

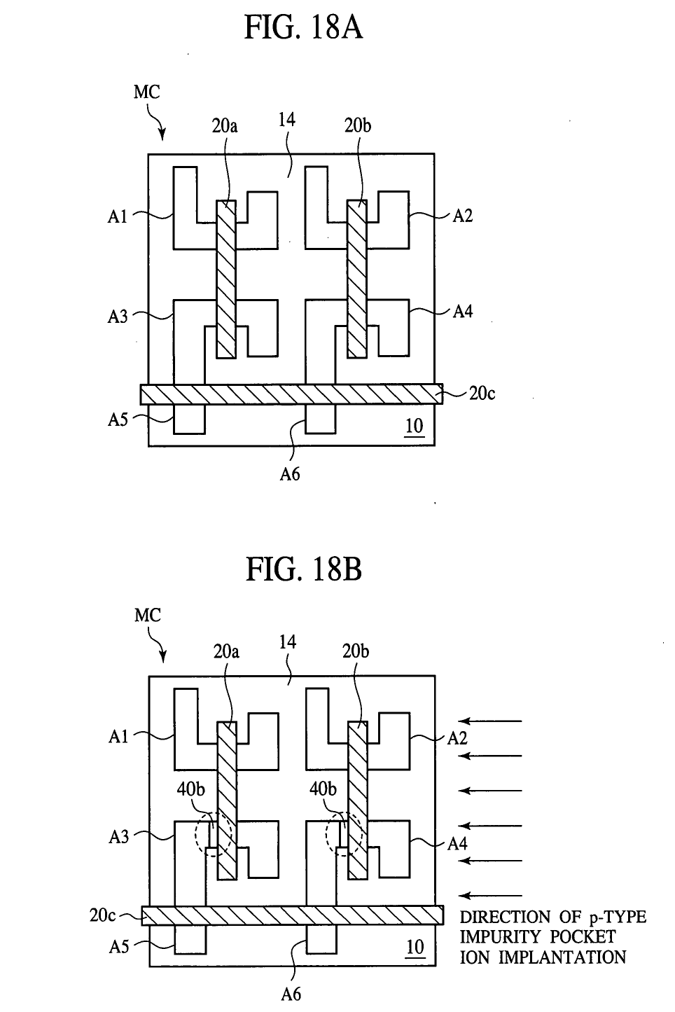

Then, in the same way as in the steps shown in FIGS. 9C, 9D and 10A, on the semiconductor substrate 10, the gate electrodes 20a, 20b, 20c are formed with a gate insulating film formed therebetween (FIG. 18A). The gate electrode 20a is common between the load transistor L1 and the driver transistor D1, the gate electrode 20b is common between the load transistor L2 and the driver transistor D2, and the gate electrode 20c is common between the transfer transistor T1 and the transfer transistor T2.

Next, in the same way as in the step shown in FIG. 10B, for the load transistors L1, L2, the driver transistors D1, D2 and the transfer transistors T1, T2, the ion implantation is made to form the LDD regions. The ion implantation is made with a photoresist film prepared by lithography as the mask respectively into the region where the PMOS transistors are to be formed and into the region where the NMOS transistors are to be formed. The ion implantation may be made in one direction slanted toward the source side or the drain side with respect to the semiconductor substrate 10 surface.

Next, the pocket ion implantation is made for the driver transistors D1, D2.

That is, first, a photoresist film which covers the regions where the load transistors L1, L2 and the transfer transistors T1, T2 are to be formed and exposes the regions where the driver transistors D1, D2 are to be formed is formed by photolithography.

Next, in the same way as in the step shown in FIG. 10C, with this photoresist film and the gate electrodes 20a, 20b as the mask, the pocket ion implantation of a p-type impurity is made in one direction slanted toward the source side with respect to the semiconductor substrate 10 surface (FIG. 18B).

Thus, the pocket ion implantation is made in one direction slanted toward the source side with respect to eh semiconductor substrate 10 surface, whereby in the driver transistors D1, D2, between the drain diffused layers 34n and the channel regions are the pocket impurity-not-implanted regions 40b due to the shadow effect of the gate electrodes 20a, 20b.

In the present embodiment, the neighboring driver transistors D1, D2 are formed independent of each other and have the source diffused layers 28n and the drain diffused layers 34n arranged side by side in the same direction, whereby for the driver transistors D1, D2, the pocket ion implantation can be made in one direction slanted toward the source side with respect to the semiconductor substrate 10 surface.

After the pocket ion implantation has been made for the drive transistors D1, D2, the photoresist film used as the mask is removed.

Next, the pocket ion implantation is made for the load transistors L1, L2.

That is, first, a photoresist film which covers the regions where the driver transistors D1, D2 and the transfer transistors T1, T2 are to be formed and exposes the regions where the load transistors L1, L2 are to be formed is formed by photolithography.

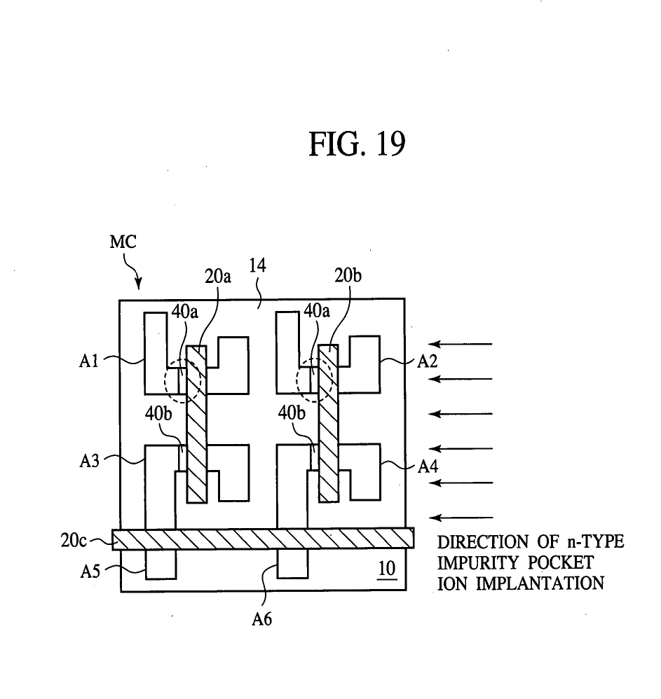

Next, in the same way as in the step shown in FIG. 10C, with this photoresist film and the gate electrodes 20a, 20b as the mask, the pocket ion implantation of an n-type impurity is made in one direction slanted toward the source side with respect to the semiconductor substrate 10 surface (FIG. 19).

Thus, the pocket ion implantation is made in one direction slanted toward the source side with respect to the semiconductor substrate 10 surface, whereby in the load transistors L1, L2, between the drain diffused layers 34p and the channel regions are the pocket impurity-not implanted regions 40a due to the shadow effect of the gate electrodes 20a, 20b.

In the present embodiment, the neighboring load transistors L1, L2 are formed independent of each other and have the source diffused layers 28p and the drain diffused layers 34p arranged side by side in the same direction, whereby for the load transistors L1, L2, the pocket ion implantation can be made in one direction slanted toward the source side with respect to the semiconductor substrate 10 surface.

After the pocket ion implantation for the load transistors L1, L2, the photoresist film used as the mask is removed.

Next, in the same way as in the step shown in FIG. 11A, the sidewall insulating films are formed on the side walls of the gate electrodes 20a, 20b, 20c.

Next, in the same way as in the step shown in FIG. 11B, for the load transistors L1, L2, the driver transistors D1, D2 and the transfer transistor T1, T2, the ion implantation is made to form the deep impurity diffused regions of the source diffused layers and the drain diffused layers. The ion implantation for forming the deep impurity diffused regions is made with a photoresist film prepared by lithography as the mask respectively into the region where the PMOS transistors are to be formed and into the region where the NMOS transistors are to be formed.

Next, in the same way as in the step shown in FIG. 11C, silicide films are formed on the gate electrodes 20a, 20b, 20c and on the source diffused layers and the on the drain diffused layers.

Hereafter, on the semiconductor substrate 10 with the load transistors L1, L2, the driver transistors D1, D2 and the transfer transistors T1, T2 formed on, interconnection layers are suitably formed by the usual semiconductor device manufacturing process.

Thus, the semiconductor device according to the present embodiment is manufactured.

As described above, according to the present embodiment, the load transistors L1, L2 and the driver transistors D1, D2 have the source diffused layers and the drain diffused layers arranged side by side in the same direction, which allows the pocket ion implantation to be made in one direction slanted toward the source side with respect to the semiconductor substrate 10 surface, whereby the GIDL can be decreased, and the electric power consumption of the semiconductor device in stand-by can be decreased.

In the above, in the semiconductor device of the circuit structure illustrated in FIG. 12, the present invention is applied to the SRAM circuit block 44. The present invention is applied to the SRAM circuit block 44 which is dominant in the leak current of the whole LSI, whereby the increase of the chip size of the semiconductor device is suppressed while the electric power consumption of the semiconductor device in stand-by can be decreased. However, the present invention is not applied essentially to the SRAM circuit and is applicable the logic circuit 46 which is also dominant in the leak current of the whole LSI. The present invention is also applicable to the CPU circuit block 48 and the peripheral circuit block 50 including the booster circuit, the step-down transformer circuit, etc.

The layout of the SRAM cell array illustrated in FIG. 15 can be changed so that for not only the load transistors L1, L2 and the driver transistors D1, D2 but also the transfer transistors T1, T2, the pocket ion implantation can be made in one direction slanted toward the source side with respect to the semiconductor substrate 10 surface.

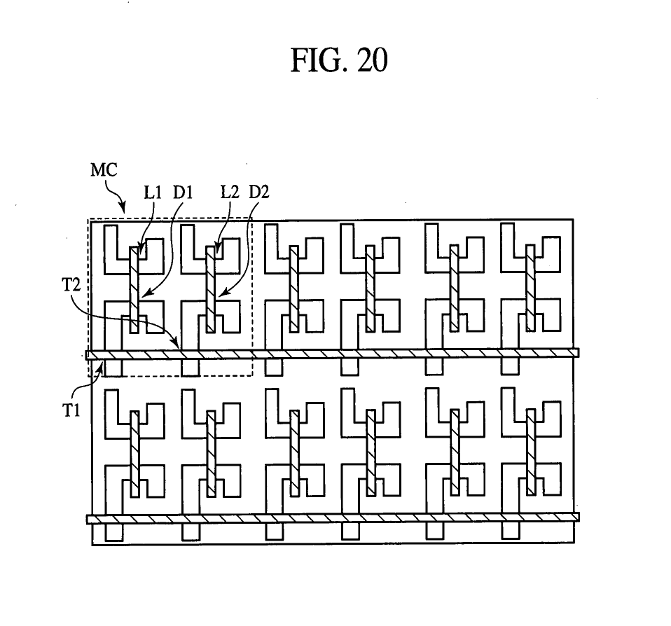

To be specific, as illustrated in FIG. 20, for the SRAM cells MC neighboring to each other column-wise (vertically as viewed in the drawing) as well as those neighboring row-wise, the load transistor1s L1, L2, the driver transistors D1, D2 and the transfer transistors T1, T2 are arranged in the same direction. The SRAM cells MC are thus arranged, whereby for the transfer transistors T1, T2 as well, the pocket ion implantation can be made in one direction slanted toward the source side with respect to the semiconductor substrate 10 surface.

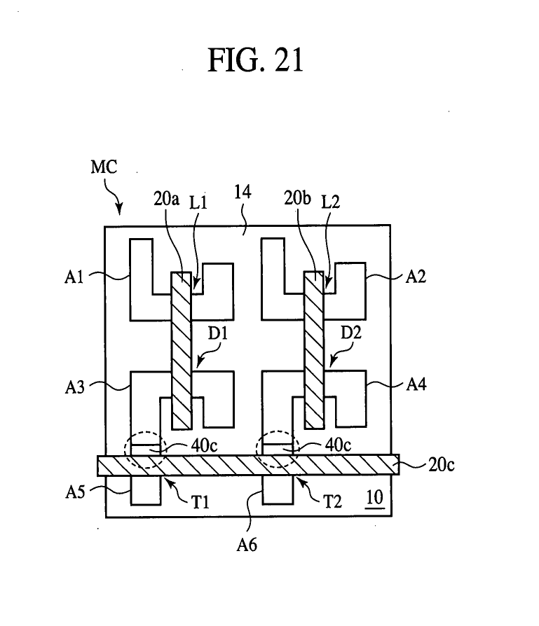

FIG. 21 illustrates the SRAM cell MC which is arranged as illustrated in FIG. 20, whereby for the transfer transistors T1, T2, the pocket ion implantation is made in one direction slanted toward the source side with respect to the semiconductor substrate 10 surface.

As illustrated, for the transfer transistors T1, T2, between the drain diffused layers and the channel regions are the pocket impurity-not-implanted regions 40c due to the shadow effect of the gate electrodes 20c.

As described above, for the transfer transistors T1, T2, the pocket ion implantation may be made in one direction slanted toward the source side with respect to the semiconductor substrate 10 surface. Thus, for the transfer transistors T1, T2, the GIDL can be decreased, and the electric power consumption of the semiconductor device in stand-by can be further decreased.

In the above, for the load transistors L1, L2 and the driver transistors D1, D2, the pocket ion implantation is made in one direction slanted toward the source side with respect to the semiconductor substrate 10 surface, but for either of the load transistors L1, L2 and the driver transistors D1, D2, the pocket ion implantation may be made in one direction slanted toward the source side with respect to the semiconductor substrate 10 surface.

All the SRAM cells MC may not have the source diffused layers and the drain diffused layers of the load transistors L1, L2 and the driver transistors D1, D2 arranged side by side in the same direction.

### A Third Embodiment

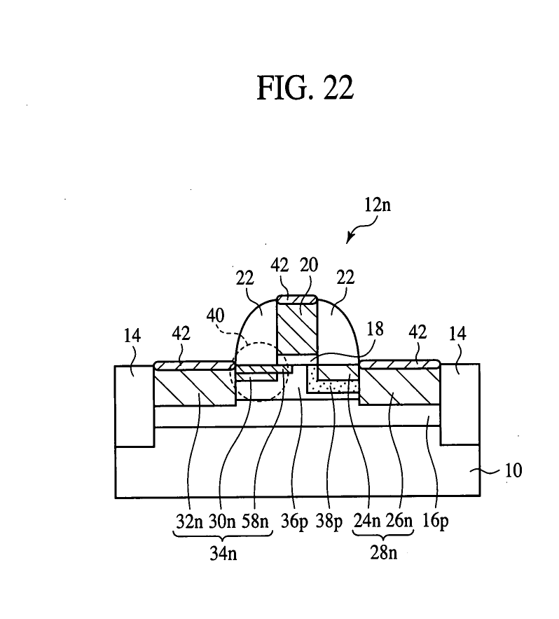

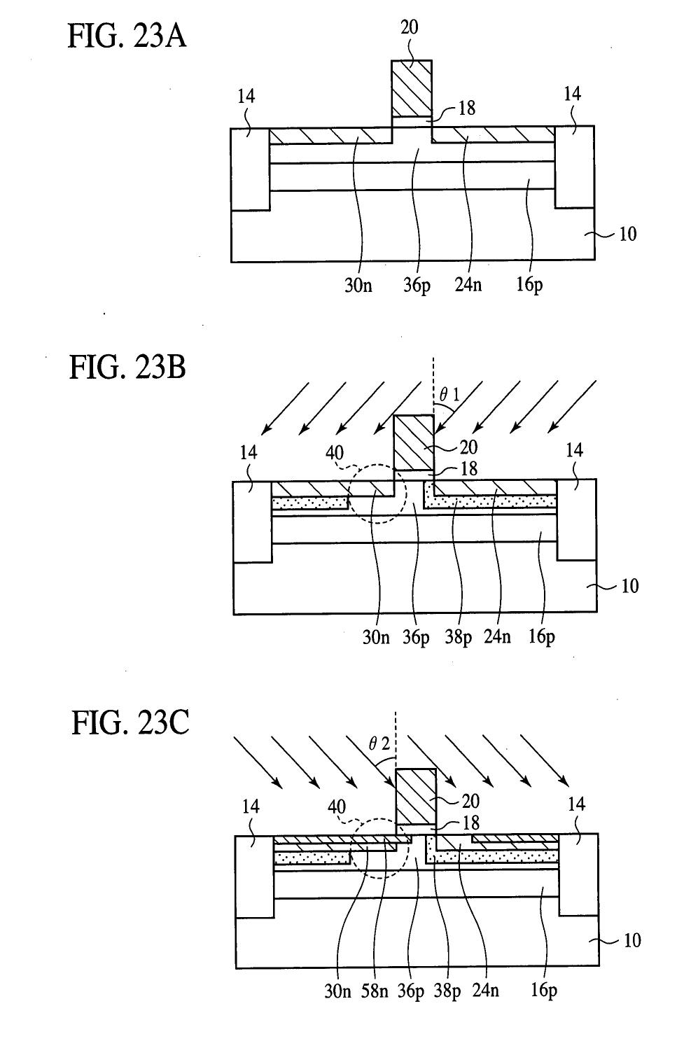

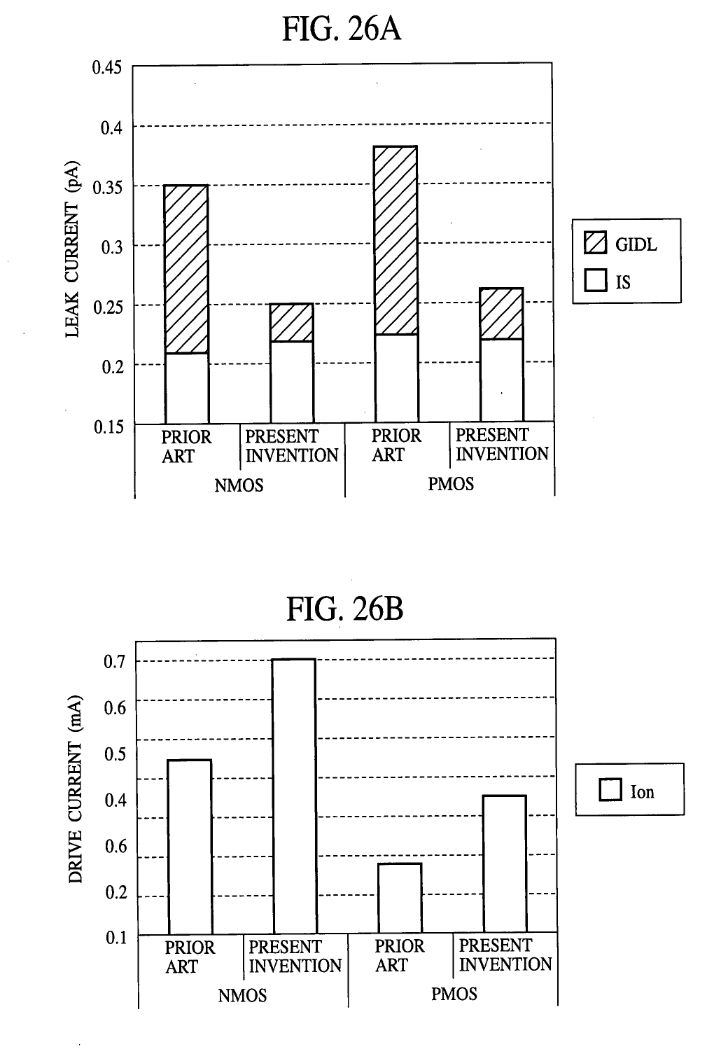

The semiconductor device and the method of manufacturing the same according to a third embodiment of the present invention will be explained with reference to FIGS. 22, 23 and 26. FIG. 22 is a diagrammatic sectional view showing the structure of an NMOS transistor of the semiconductor device according to the present embodiment. FIG. 23 is sectional views showing the method of manufacturing the semiconductor device according to the present embodiment. FIG. 26 is graphs of the leak current and the drive current of the NMOS transistor of the semiconductor device according to the present embodiment. The same members of the present embodiment as those of the semiconductor device and the method of manufacturing the same according to the first and the second embodiments are represented by the same reference numbers not to repeat or to simplify their explanation.

First, the structure of the semiconductor device according to the present embodiment will be explained with reference to FIG. 22.

The basic constitution of the semiconductor device according to the present embodiment is substantially the same as that of the semiconductor device according to the first embodiment. In the semiconductor device according to the present embodiment, an impurity of the same conduction type as the source diffused layer and the drain diffused layer is further ion-implanted in one direction slanted toward the drain side with respect to the semiconductor substrate 10 surface. In the present embodiment, the MOS transistor 12 is an NMOS transistor 12n.

In a semiconductor substrate 10, a device isolation film 14 for defining an active region is formed.

In the semiconductor substrate 10 with the active region defined, a p-type well 16p is formed.

On the semiconductor substrate 10, a gate electrode 20 is formed with a gate insulating film 18 formed therebetween. A sidewall insulating film 22 is formed on the side walls of the gate electrode 20.

In the semiconductor substrate 10 on the source side of the gate electrode 20, an n-type source diffused layer 28n is formed of an LDD region 24n formed by self-alignment with the gate electrode 20 and an impurity diffused layer 26n formed by self-alignment with the gate electrode 20 and the sidewall insulating film 22. In the semiconductor substrate 10 on the drain side of the gate electrode 20, an n-type drain diffused layer 34n is formed of an LDD region 30n formed by self-alignment with the gate electrode 20 and an impurity diffused layer 32n formed by self-alignment with the gate electrode 20p and the sidewall insulating film 22. Between the source diffused layer 28n and the drain diffused layer 34n is a p-type channel region 36p.

A p-type pocket region 38p is formed between the source diffused layer 28n and the channel region 36p. Between the drain diffused layer 34n and the channel region 36p, no pocket region is formed. That is, between the drain diffused layer 34n and the channel region 36p is a pocket impurity-not-implanted region 40.

Furthermore, the drain diffused layer 34n includes an n-type impurity diffused region 58n which is shallower than the LDD region 30n and has the end on the gate electrode 20 side extended up to below the gate electrode 20.

Silicide films 42 are formed on the gate electrode 20, the source diffused layer 28n and the drain diffused layer 34n.

The semiconductor device according to the present embodiment is characterized mainly in that, as in the semiconductor device according to the first embodiment, the pocket region 38p is formed selectively between the source diffused layer 28n and the channel region 36p of the NMOS transistor 12n, and between the drain diffused layer 34n and the channel region 36p is the pocket impurity-not-implanted region 40. Thus, the GIDL of the NMOS transistor 12n can be decreased, and the electric power consumption of the semiconductor device in stand-by can be decreased.

Furthermore, the semiconductor device according to the present embodiment is also characterized mainly in that the drain diffused layer 34n includes the n-type impurity diffused region 58n which is shallower than the LDD region 30n and has the end on the gate electrode 20 side extended up to below the gate electrode 20. As will be described later, the n-type impurity diffused region 58n is formed by ion-implanting an n-type impurity in one direction slanted toward the drain side with respect to the semiconductor substrate 10 surface.

In the semiconductor device according to the present embodiment, the n-type impurity diffused region 58n shortens the effective channel length of the NMOS transistor 12n. Accordingly, the drive current of the n-MOS transistor 12n can be increased.

FIG. 26A is a graph of the leak current of the NMOS transistor of the semiconductor device according to the present embodiment, and FIG. 26B is a graph of the drive current. FIGS. 26A and 26B respectively also show the leak current and the drive current of the NMOS transistor manufactured by the prior art.

As evident in the graph of FIG. 26A, the prior art and the present embodiment do not much differ in the IS of the components of the leak current of the NMOS transistor. As for the GIDL, the present embodiment deceases the GIDL down to about ¼ the GIDL of the prior art. Thus, the present embodiment decreases the leak current as a whole down to about a half of the leak current of the prior art.

Furthermore, as evident in the graph of FIG. 26B, the preset embodiment increases the drive current of the NMOS transistor up to about 1.5 times that of the prior art.

As described above, according to the present embodiment, the leak current of the NMOS transistor can be decreased, and the drive current of the NMOS transistor can be increased.

Next, the method of manufacturing the semiconductor device according to the present embodiment will be explained with reference to FIG. 23.

First, in the same way as in forming the NMOS transistor by the method of manufacturing the semiconductor device according to the first embodiment illustrated in FIGS. 9A to 10B, the NMOS transistor is formed up to the LDD regions 24n, 30n (FIG. 23A).

Then, with the gate electrode 20 as the mask, the pocket ion implantation of a p-type impurity is made in one direction slanted toward the source side with respect to the semiconductor substrate 10 surface to form the pocket region 38p (FIG. 23B). In this pocket ion implantation, boron as a p-type impurity is ion-implanted at an incidence angle which is slanted by, e.g., 30° toward the source side under conditions, e.g., of a 20 keV acceleration energy and a 2×10¹³ cm⁻² dose. As the p-type impurity, indium or others may be used.

In the same way as in the method of manufacturing the semiconductor device according to the first embodiment, the pocket ion implantation is made in one direction slanted toward the source side with respect to the semiconductor substrate 10 surface, whereby the pocket region 38p is formed selectively between the source diffused layer 28n and the channel region 36p of the NMOS transistor 12n while between the drain diffused layer 34n and the channel region 36p can be the pocket impurity-not-implanted region 40. Accordingly, the GIDL of the NMOS transistor 12n can be decreased, and the electric power consumption of the semiconductor device in stand-by can be decreased.

The incidence angle θ1 for the pocket ion implantation can be suitably set in the range of 0°<θ1<90°, depending on a height of the gate electrode 20, etc.

Then, with the gate electrode 20 as the mask, the ion implantation of an n-type impurity is made in one direction slanted toward the drain side with respect to the semiconductor substrate 10 surface. Thus, in the semiconductor substrate 10 on the drain side of the gate electrode 20, the n-type impurity diffused region 58n which is shallower than the LDD region 30n and has the end on the gate electrode 20 side extended up to below the gate electrode 20 is formed (FIG. 23C). In the ion implantation for forming the n-type impurity diffused region 58n, arsenic as an n-type impurity is ion-implanted at an incidence angle which is slanted by, e.g., 30° toward the drain side under conditions, e.g., of a 10 keV acceleration energy and a 4×10¹³ cm⁻² dose. As the n-type impurity, phosphorus or others may be used.

The ion implantation of the n-type impurity is thus made in one direction slanted toward the drain side with respect to the semiconductor substrate 10 surface to thereby form the n-type impurity diffused regions 58n, whereby the effective channel length of the NMOS transistor 12n can be decreased. Accordingly, the drive current of the NMOS transistor 12n can be increased.

When it is assumed that the ion implantation of the n-type impurity is made in one direction slanted toward the source side with respect to the semiconductor substrate 10 surface, this n-type impurity and the p-type impurity implanted by the pocket ion implantation will compensate each other. Resultantly, the effective channel length cannot be decreased, and even the effect of the pocket ion implantation is lost. Accordingly, the ion implantation of the n-type impurity must be made in one direction slanted toward the drain side with respect to the semiconductor substrate 10 surface.

The incidence angle θ2 of the ion implantation for forming the n-type impurity diffused region 58n can be suitably set in the range of 0°<θ2<90° depending on a height of the gate electrode 20, etc.

The following steps are the same as the steps for forming the NMOS transistor of the method of manufacturing the semiconductor device according to the first embodiment as shown in FIGS. 11A to 11C, and their explanation is not repeated.

As described above, according to the present embodiment, the pocket ion implantation is made in one direction slanted toward the source side with respect to the semiconductor substrate 10 surface, whereby the pocket region 38p can be formed selectively between the source diffused layer 28n and the channel region 36p of the NMOS transistor 12n, while between the drain diffused layer 34n and the channel region 36p can be the pocket impurity-not-implanted region 40. Accordingly, the GIDL of the NMOS transistor 12n can be decreased, and the electric power consumption of the semiconductor device in stand-by can be decreased.

Furthermore, according to the present embodiment, the ion implantation of the n-type impurity is made in one direction slanted toward the drain side with respect to the semiconductor substrate 10 surface to thereby form in the semiconductor substrate 10 on the drain side of the gate electrode 20 the n-type impurity diffused region 58n having the end on the gate electrode 20 side extended up to below the gate electrode 20, whereby the effective channel length of the NMOS transistor 12n can be decreased. Accordingly, the drive current of the NMOS transistor 12n can be increased.

In the above, after the pocket ion implantation for forming the pocket region 38p has been made, the ion implantation for forming the n-type impurity diffused region 58n is made. However, the sequence of making these steps may be reversed. That is, after the ion implantation for forming the n-type impurity diffused region 58n has been made, the pocket ion implantation for forming the pocket region 38p may be made.

### A Fourth Embodiment

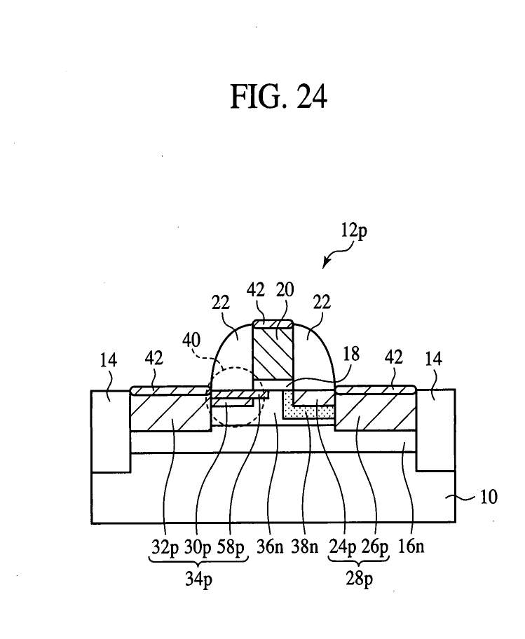

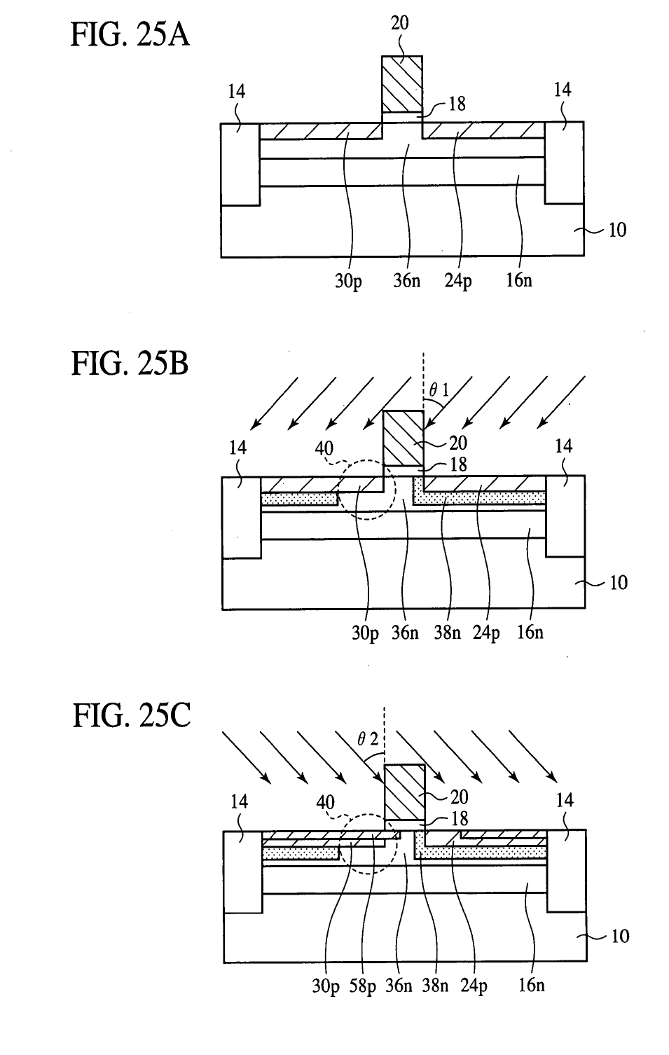

The semiconductor device and the method of manufacturing the same according to a fourth embodiment of the present invention will be explained with reference to FIGS. 24 to 26. FIG. 24 is a diagrammatic sectional view showing the structure of a PMOS transistor of the semiconductor device according to the present embodiment. FIG. 25 is sectional views showing the method of manufacturing the semiconductor device according to the present embodiment. FIG. 26 is graphs of the leak current and the drive current of the PMOS transistor of the semiconductor device according to the present embodiment. The same members of the present embodiment as those of the semiconductor device and the method of manufacturing the same according to the first and the second embodiments are represented by the same reference numbers not to repeat or to simplify their explanation.

First, the structure of the semiconductor device according to the present embodiment will be explained with reference to FIG. 24.

The basic constitution of the semiconductor device according to the present embodiment is substantially the same as that of the semiconductor device according to the first embodiment. In the semiconductor device according to the present embodiment, an impurity of the same conduction type as the source diffused layer and the drain diffused layer is further ion-implanted in one direction slanted toward the drain side with respect to the semiconductor substrate 10 surface. In the present embodiment, the MOS transistor 12 is a PMOS transistor 12p.

In a semiconductor substrate 10, a device isolation film 14 for defining an active region is formed.

In the semiconductor substrate 10 with the active region defined, an n-type well 16n is formed.

On the semiconductor substrate 10, a gate electrode 20 is formed with a gate insulating film 18 formed therebetween. A sidewall insulating film 22 is formed on the side walls of the gate electrode 20.

In the semiconductor substrate 10 on the source side of the gate electrode 20, a p-type source diffused layer 28p is formed of an LDD region 24p formed by self-alignment with the gate electrode 20 and an impurity diffused region 26p formed by self-alignment with the gate electrode 20 and the sidewall insulating film 22. In the semiconductor substrate 10 on the drain side of the gate electrode 20, a p-type drain diffused layer 34p is formed of an LDD region 30p formed by self-alignment with the gate electrode 20 and an impurity diffused region 32p formed by self-alignment with the gate electrode 20 and the sidewall insulating film 22. Between the source diffused layer 28p and the drain diffused layer 34p is an n-type channel region 36n.

An n-type pocket region 38n is formed between the source diffused layer 28p and the channel region 36n. Between the drain diffused layer 34p and the channel region 36n, no pocket region is formed. That is, between the drain diffused layer 34p and the channel region 36n is a pocket impurity-not-implanted region 40.

Furthermore, the drain diffused layer 34p includes a p-type impurity diffused region 58p which is shallower than the LDD region 30p and has the end on the gate electrode 20 side extended up to below the gate electrode 20.

Silicide films 42 are formed on the gate electrode 20, the source diffused layer 28p and the drain diffused layer 34p.

The semiconductor device according to the present embodiment is characterized mainly in that, as in the semiconductor device according to the first embodiment, the pocket region 38n is formed selectively between the source diffused layer 28p and the channel region 36n of the PMOS transistor 12p, and between the drain diffused layer 34p and the channel region 36n is the pocket impurity-not-implanted region 40. Thus, the GIDL of the PMOS transistor 12 can be decreased, and the electric power consumption of the semiconductor device in stand-by can be decreased.

Furthermore, the semiconductor device according to the present embodiment is also characterized mainly in that the drain diffused layer 34p includes the p-type impurity diffused region 58p which is shallower than the LDD region 30p and has the end on the gate electrode 20 side extended up to below the gate electrode 20. As will be described alter, the p-type impurity diffused region 58p is formed by ion-implanting a p-type impurity in one direction slanted toward the drain side with respect to the semiconductor substrate 10 surface.

In the semiconductor device according to the present embodiment, the p-type impurity diffused region 58p shortens the effective channel length of the PMOS transistor 12p. Accordingly, the drive current of the PMOS transistor 12p can be increased.

FIG. 26A is a graph of the leak current of the PMOS transistor of the semiconductor device according to the present embodiment, and FIG. 26B is a graph of the drive current. FIGS. 26A and 26B respectively also show the leak current and the drive current of the PMOS transistor manufactured by the prior art.

As evident in the graph of FIG. 26A, the prior art and the present embodiment do not much differ in the IS of the components of the leak current of the PMOS transistor. As for the GIDL, the present embodiment deceases the GIDL down to about ¼ the GIDL of the prior art. Thus, the present embodiment decreases the leak current as a whole down to about a half of the leak current of the prior art.

Furthermore, as evident in the graph of FIG. 26B, the present embodiment increases the drive current of the PMOS transistor up to about twice that of the prior art.

As described above, according to the present embodiment, the leak current of the PMOS transistor can be decreased and the drive current of the PMOS transistor can be increased.

Next, the method of manufacturing the semiconductor device according to the present embodiment will be explained with reference to FIG. 25.

First, in the same way as in forming the PMOS transistor by the method of manufacturing the semiconductor device according to the first embodiment illustrated in FIGS. 9A to 10B, the PMOS transistor is formed up to the LDD regions 24p, 30p (FIG. 25A).

Then, with the gate electrode 20 as the mask, the pocket ion implantation of an n-type impurity is made in one direction slanted toward the source side with respect to the semiconductor substrate 10 surface to form the pocket region 38n (FIG. 25B). In this pocket ion implantation, phosphorus as an n-type impurity is ion-implanted at an incidence angle which is slanted by, e.g., 30° toward the source side under conditions, e.g., of a 20 keV acceleration energy and a 2×10¹³ cm⁻² dose. As the n-type impurity, arsenic or others may be used.

In the same way as in the method of manufacturing the semiconductor device according to the first embodiment, the pocket ion implantation is made in one direction slanted toward the source side with respect to the semiconductor substrate 10 surface, whereby the pocket region 38n is formed selectively between the source diffused layer 28p and the channel region 36n of the PMOS transistor 12p while between the drain diffused layer 34p and the channel region 36n can be the pocket impurity-not-implanted region 40. Accordingly, the GIDL of the PMOS transistor 12p can be decreased, and the electric power consumption of the semiconductor device in stand-by can be decreased.

The incident angle θ1 for the pocket ion implantation can be suitably set in the range of 0°<θ1<90° depending on a height of the gate electrode 20, etc.

Then, with the gate electrode 20 as the mask, the ion implantation of a p-type impurity is made in one direction slanted toward the drain side with respect to the semiconductor substrate 10 surface. Thus, in the semiconductor substrate 10 on the drain side of the gate electrode 20, the p-type impurity diffused region 58p which is shallower than the LDD region 30p and has the end on the gate electrode 20 side extended up to below the gate electrode 20 is formed (FIG. 25C). In the ion implantation for forming the p-type impurity diffused region 58p, boron as a p-type impurity is implanted at an incidence angle which is slanted by, e.g., 30° toward the drain side under conditions, e.g., of a 15 keV acceleration energy and a 3×10¹³ cm⁻² dose. As the p-type impurity, indium or others may be used.

The ion implantation of the p-type impurity is thus made in one direction slanted toward the drain side with respect to the semiconductor substrate 10 surface to thereby form the p-type impurity diffused region 58p, whereby the effective channel length of the PMOS transistor 12p can be decreased. Accordingly, the drive current of the PMOS transistor 12p can be increased.

When it is assumed that the ion implantation of the p-type impurity is made in one direction slanted toward the source side with respect to the semiconductor substrate 10 surface, this p-type impurity and the n-type impurity implanted by the pocket ion implantation will compensate each other. Resultantly, the effective channel length cannot be decreased, and even the effect of the pocket ion implantation is lost. Accordingly, the ion implantation of the p-type impurity must be made in one direction slanted toward the drain side with respect to the semiconductor substrate 10 surface.

The incidence angle θ2 of the ion implantation for forming the p-type impurity diffused region 58p can be suitably set in the range of 0°<θ2<90° depending on a height of the gate electrodes 20, etc.

The following steps are the same as steps for forming the PMOS transistor of the method of manufacturing the semiconductor device according to the first embodiment as shown in FIGS. 11A to 11C, and their explanation is not repeated.

As described above, according to the present embodiment, the pocket ion implantation is made in one direction slanted toward the source side with respect to the semiconductor substrate 10 surface, whereby the pocket region 38n can be formed selectively between the source diffused layer 28p and the channel region 36n of the PMOS transistor 12p, while between the drain diffused layer 34p and the channel region 36n can be the pocket impurity-not-implanted region 40. Accordingly, the GIDL of the PMOS transistor 12p can be decreased, and the electric power consumption of the semiconductor device in stand-by can be decreased.

Furthermore, according to the present embodiment, the ion implantation of the p-type impurity is made in one direction slanted toward the drain side with respect to the semiconductor substrate 10 surface to thereby form in the semiconductor substrate 10 on the drain side of the gate electrode 20 the p-type impurity diffused region 58p having the end on the gate electrode 20 side extended up to below the gate electrode 20, whereby the effective channel length of the PMOS transistor 12p can be decreased. Accordingly, the drive current of the PMOS transistor 12p can be increased.

In the above, after the pocket ion implantation for forming the pocket region 38n has been made, the ion implantation for forming the p-type impurity diffused region 58p is made. However, the sequence of making these steps may be reversed. That is, after the ion implantation for forming the p-type impurity diffused region 58p has been made, the pocket ion implantation for forming the pocket region 38n may be made.

### A Fifth Embodiment

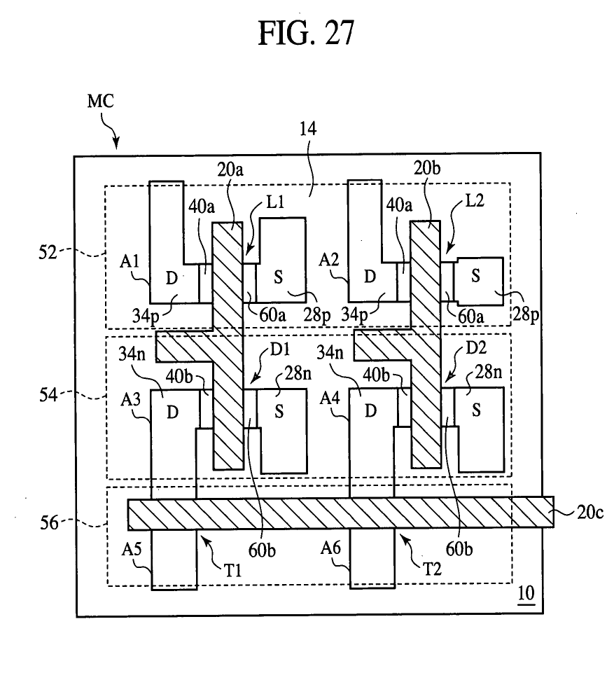

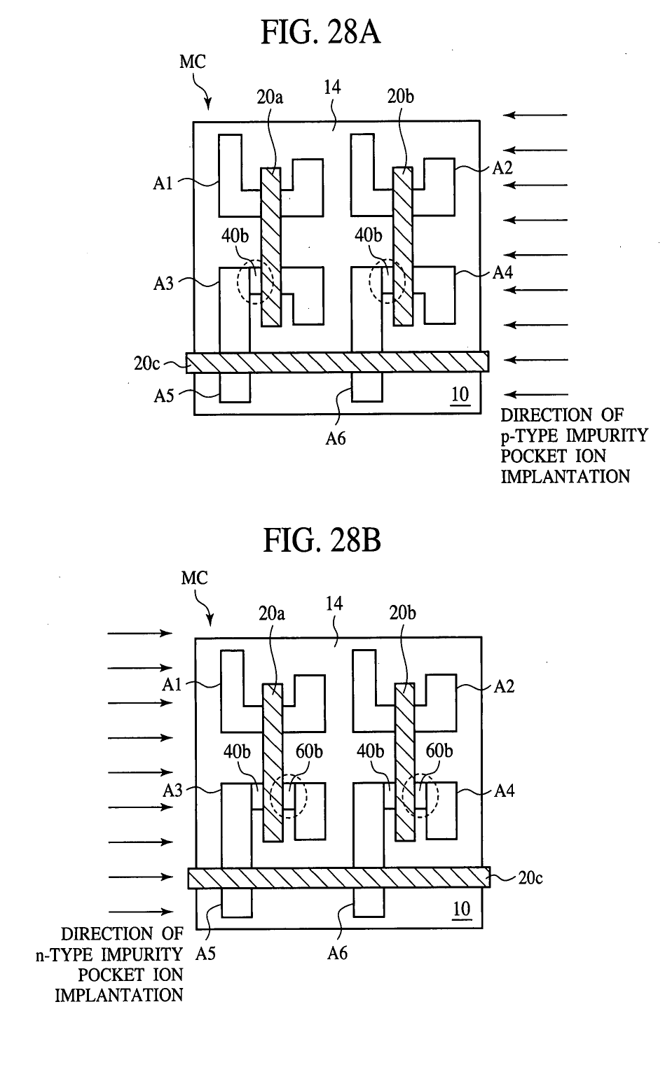

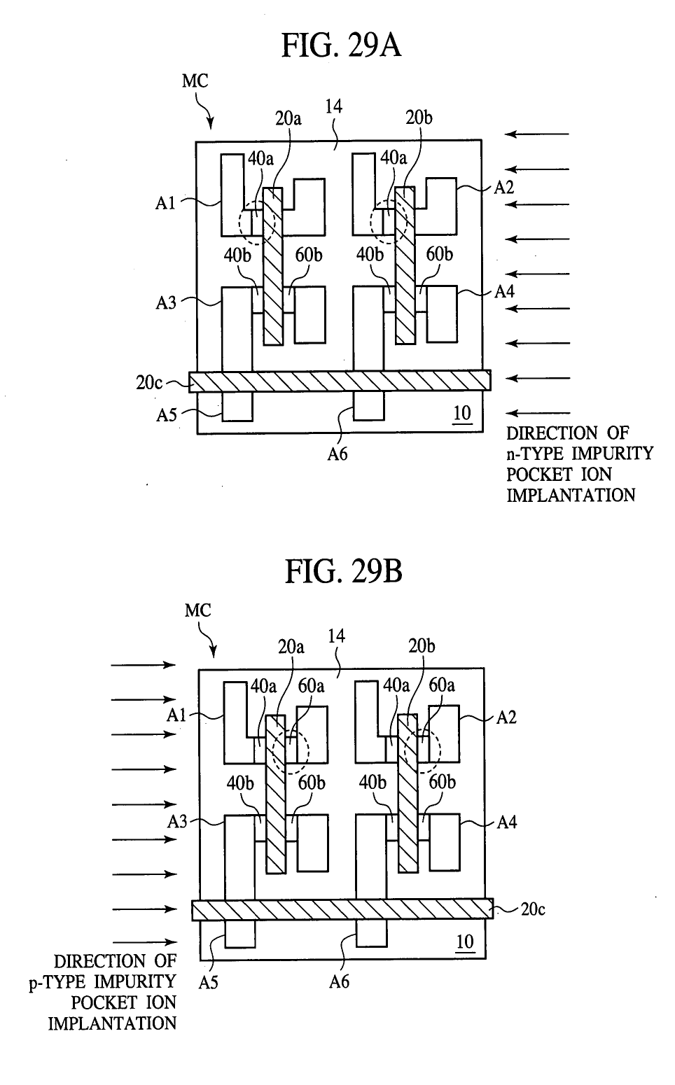

The semiconductor device and the method of manufacturing the same according to a fifth embodiment of the present invention will be explained with reference to FIGS. 27 to 29. FIG. 27 is a diagrammatic plan view showing the layout of an SRAM cell of the semiconductor device according to the present embodiment. FIGS. 28 and 29 are plan views showing the method of manufacturing the semiconductor device according to the present embodiment. The same members of the present embodiment as those of the semiconductor device and the method of manufacturing the same according to the first to the fourth embodiments are represented by the same reference numbers not to repeat or to simplify their explanation.

First, the structure of the semiconductor device according to the present embodiment will be explained with reference to FIG. 27.

The basic constitution of the semiconductor device according to the present embodiment is substantially the same as that of the semiconductor device according to the second embodiment. The semiconductor device according to the present embodiment uses the NMOS transistors 12n according to the third embodiment as the driver transistors D1, D2 forming an SRAM cell MC and uses the PMOS transistors 12p according to the fourth embodiment as the load transistors L1, L2 forming the SRAM cell MC.

As illustrated, in the SRAM cell MC of the semiconductor device according to the present embodiment, as in the semiconductor device according to the second embodiment, the neighboring load transistors L1, L2 are formed independent of each other and have the source diffused layers 28p and the source diffused layers 34p arranged side by side in the same direction, and the neighboring driver transistors D1, D2 are formed independent of each other and have the source diffused layers 28n and the drain diffused layers 34n arranged side by side in the same direction.

That is, in the load transistor part 52, the active region A1 where the load transistor L1 is formed and the active region A2 where the load transistor L2 is formed are isolated from each other by the device isolation film 14. The neighboring load transistors L1, L2 are formed thus independent of each other and have the source diffused layers 28p and the drain diffused layers 34p arranged side by side in the same direction. In the load transistors L1, L2, pocket regions are formed selectively between the source diffused layers 28p and the channel regions, and between the drain diffused layers 34p and the channel regions are pocket impurity-not-implanted regions 40a.

Furthermore, in the load transistors L1, L2, as in the PMOS transistor 12p according to the fourth embodiment, the drain diffused layer 34p includes the p-type impurity diffused region 58p which is shallower than the LDD region 30p and has the end on the gate electrode 20 side extended up to below the gate electrode 20 (refer to FIG. 24). In the semiconductor substrate 10 on the source sides of the gate electrodes 20a, 20b of the load transistors L1, L2 are impurity-not-implanted regions 60a where a p-type impurity by ion implantation for forming the p-type impurity diffused regions 58p is not implanted due to the shadow effect of the gate electrodes 20a, 20b.

In the driver transistor part 54, the active region A3 where the driver transistor D1 is formed and the active region A4 where the driver transistor D2 is formed are isolated from each other by the device isolation film 14. The neighboring driver transistors D1, D2 are formed thus independent of each, other and has the source diffused layers 28n and the drain diffused layers 34n arranged side by side in the same direction. In the driver transistors D1, D2, pocket regions are formed selectively between the source diffused layers 38n and the channel regions, and between the drain diffused layers 34n and the channel regions are pocket impurity-not-implanted regions 40b.

Furthermore, in the driver transistors D1, D2, as in the NMOS transistor 12n according to the third embodiment, the drain diffused layer 34n includes the n-type impurity diffused region 58n which is shallower than the LDD region 30n and has the end of the gate electrode 20 side extended up to below the gate electrode 20 (refer to FIG. 22). In the semiconductor substrate 10 on the source sides of the gate electrodes 20a, 20b of the driver transistors D1, D2 are impurity-not-implanted regions 60b where an n-type impurity by ion implantation for forming the n-type impurity diffused regions 58n is not implanted due to the shadow effect of the gate electrodes 20a, 20b.

In the transfer transistor part 56, the active region A5 where the transfer transistor T1 is formed is connected to the active region A3 where the driver transistor D1 is formed. The active region A6 where the transfer transistor T2 is formed is connected to the active region A4 where the driver transistor D2 is formed.

The load transistor L1 and the driver transistor D1 have a gate electrode 20a in common. The load transistor L2 and the driver transistor D2 have a gate electrode 20b in common. The transfer transistors T1, T2 have a gate electrode 20c in common.

The SRAM cell MC illustrated in FIG. 27 is repeatedly arrange row-wise and column-wise as in the semiconductor device according to the second embodiment illustrated in FIG. 15, forming a memory cell array.

The semiconductor device according to the present embodiment is characterized mainly in that, as in the semiconductor device according to the second embodiment, in the SRAM cell MC, the neighboring load transistors L1, L2 are formed independent of each other and have the source diffused layers 28 and the drain diffused layers 34p arranged side by side in the same direction, and the neighboring driver transistors D1, D2 are formed independent of each other and have the source diffused layers 28n and the drain diffused layers 34n arranged side by side in the same direction. This allows the pocket ion implantation to be made in one direction slanted toward the source side with respect to the semiconductor substrate 10 surface for the load transistors L1, L2 and the driver transistors D1, D2, whereby the GIDL can be decreased, and the electric power consumption of the semiconductor device in stand-by can be decreased.

Furthermore, the semiconductor device according to the present embodiment is characterized mainly in that, the drain diffused layer 34p of the load transistors L1, L2 includes the p-type impurity diffused region 58p which is shallower than the LDD region 30p and has the end on the gate electrode 20 side extended up to below the gate electrode 20 (refer to FIG. 24), and the drain diffused layer 34n includes the n-type impurity diffused region 58n which is shallower than the LDD region 30n and has the end of the gate electrode 20 side extended up to below the gate electrode 20 (refer to FIG. 22).

In the semiconductor device according to the present embodiment, as described above, the load transistors L1, L2 and the driver transistors D1, D2 have the source diffused layers and the drain diffused layers arranged side by side in the same direction. This allows, the ion implantation of a p-type impurity for the load transistors L1, L2 and the ion implantation of an n-type impurity for the driver transistors D1, D2 to be made in one direction slanted toward the drain side with respect to the semiconductor substrate 10 surface to respectively form the p-type impurity diffused regions 58p and the n-type impurity diffused regions 58n. Thus, the effective channel length of the load transistors L1, L2 and the driver transistors D1, D2 can be decreased, and the dive current can be increased.

Next, the method of manufacturing the semiconductor device according to the present embodiment will be explained with reference to FIGS. 28 and 29.

First, in the same way as in the method of manufacturing the semiconductor device according to the second embodiment shown in FIGS. 17A to 18A, the semiconductor device is manufactured up to the gate electrodes 20a, 20b, 20c.

Next, for the load transistors L1, L2, the driver transistors D1, D2 and the transfer transistors T1, T2, ion implantation is made to form the LDD regions. The ion implantation for forming the LDD regions is made with a photoresist film prepared by lithography as the mask respectively into the region where the PMOS transistors are to be formed and the region where the NMOS transistors are to be formed. The ion implantation for forming the LDD regions may be made in one direction slanted toward the source side or the drain side with respect to the semiconductor substrate 10 surface.

Next, the pocket ion implantation is made for the driver transistors D1, D2.

That is, first, a photoresist film which covers the regions where the load transistors L1, L2 and the transfer transistors T1, T2 are to be formed and exposes the regions where the drive transistors D1, D2 are to be formed is formed by photolithography.

Next, in the same way as in the step shown in FIG. 23B, with this photoresist film and the gate electrodes 20a, 20b as the mask, the pocket ion implantation of a p-type impurity is made in one direction slanted toward the source side with respect to the semiconductor substrate 10 surface (FIG. 28A).

Thus, the pocket ion implantation is made in one direction slanted toward the source side with respect to the semiconductor substrate 10 surface, whereby in the driver transistors D1, D2, between the drain diffused layers 34n and the channel regions are the pocket impurity-not-implanted regions 40b due to the shadow effect due to the gate electrodes 20a, 20b.

In the present embodiment, the neighboring driver transistors D1, D2 are formed independent of each other and have the source diffused layers 28n and the drain diffused layers 34n arranged side by side in the same direction, whereby for the driver transistors D1, D2, the pocket ion implantation can be made in one direction slanted toward the source side with respect to the semiconductor substrate 10 surface.

Then, in the same way as in the step shown in FIG. 23C, with the photoresist film and the gate electrodes 20a, 20b as the mask, the ion implantation of an n-type impurity is made in one direction slanted toward the drain side with respect to the semiconductor substrate 10 surface (FIG. 28B). Thus, in the semiconductor substrate 10 on the drain sides of the gate electrodes 20a, 20b of the driver transistors D1, D2, the n-type impurity diffused regions 58n (refer to FIG. 23C) which are shallower than the LDD regions 20n and have the ends on the gate electrode 20 sides extended up to below the gate electrodes 20 are formed. In the semiconductor substrate 10 on the source sides of the gate electrodes 20a, 20b of the driver transistors D1, D2 are the impurity-not-implanted regions 60b where the n-type impurity by the ion implantation for forming the n-type impurity diffused regions 58n is not ion-implanted due to the shadow effect of the gate electrodes 20a, 20b.

The ion implantation of the n-type impurity is thus made in one direction slanted toward the drain side with respect to the semiconductor substrate 10 surface to thereby form the n-type impurity diffused regions 58n, whereby the effective channel length of the driver transistors D1, D2 can be decreased. Accordingly, the drive current of the driver transistors D1, D2 can be increased.

After the pocket ion implantation of the p-type impurity and the ion implantation of the n-type impurity have been made for the driver transistors D1, D2, the photoresist film used as the mask is removed.

Then, the pocket ion implantation is made for the load transistors L1, L2.

That is, first, a photoresist film which covers the regions where the driver transistors D1, D2 and the transfer transistors T1, T2 are to be formed and exposes the regions where the load transistors L1, L2 are to be formed is formed by photolithography.

Then, in the same way as in the step of FIG. 25B, with this photoresist film and the gate electrodes 20a, 20b as the mask, the pocket ion implantation of an n-type impurity is made in one direction slanted toward the source side with respect to the semiconductor substrate 10 surface (FIG. 29A).

Thus, the pocket ion implantation is made in one direction slanted toward the source side with respect to the semiconductor substrate 10 surface, whereby in the load transistors L1, L2, between the drain diffused layers 34p and the channel regions are the pocket impurity-not-implanted regions 40a due to the shadow effect of the gate electrodes 20a, 20b.

In the present embodiment, the neighboring load transistors L1, L2 are formed independent of each other and have the source diffused layers 28p and the drain diffused layer 34p arranged side by side in the same direction, whereby for the load transistors L1, L2, the pocket ion implantation can be made in one direction slanted toward the source side with respect to the semiconductor substrate 10 surface.

Then, in the same way as in the step shown in FIG. 25C, with the photoresist film and the gate electrodes 20a, 20b as the mask, the ion implantation of a p-type impurity is made in one direction slanted toward the drain side with respect to the semiconductor substrate 10 surface (FIG. 29B). Thus, in the semiconductor substrate 10 on the drain sides of the gate electrodes 20a, 20b of the load transistors L1, L2, the p-type impurity diffused regions 58p (refer to FIG. 25C) which are shallower than the LDD regions 30p and have the ends on the gate electrode 20 sides extended up to below the gate electrodes 20 are formed. In the semiconductor substrate 10 on the source sides of the gate electrodes 20a, 20b of the load transistors L1, L2 are the impurity-not-implanted regions 60a where the p-type impurity by the ion implantation for forming the p-type impurity diffused regions 58p is not ion-implanted due to the shadow effect of the gate electrodes 20a, 20b.

The ion implantation of the p-type impurity is thus made in one direction slanted toward the drain side with respect to the semiconductor substrate 10 surface to thereby form the p-type impurity diffused regions 58p, whereby the effective channel length of the load transistors L1, L2 can be decreased. Accordingly, the drive current of the load transistors L1, L2 can be increased.

After the pocket ion implantation of the n-type impurity and the ion implantation of the p-type impurity have been made for the load transistors L1, L2, the photoresist film used as the mask is removed.

The following steps including the step of forming a sidewall insulating film and after the step of forming the sidewall insulating film are the same as those of the method of manufacturing the semiconductor device according to the second embodiment, and their explanation is not repeated.

As described above, according to the present embodiment, the load transistors L1, L2 and the driver transistors D1, D2 have the source diffused layers and the drain diffused layers arranged side by side in the same direction, which allows the pocket ion implantation to be made in one direction slanted toward the source side with respect to the semiconductor substrate 10 surface, whereby the GIDL can be decreased, and the electric power consumption of the semiconductor device in stand-by can be decreased.

Furthermore, according to the present embodiment, for the load transistors L1, L2, the ion implantation of a p-type impurity is made in one direction slanted toward the drain side with respect to the semiconductor substrate 10 surface to thereby form the p-type impurity diffused regions having the ends on the gate electrode sides extended up to below the gate electrodes, and for the driver transistors D1, D2, the ion implantation of an n-type impurity is made to thereby form the n-type impurity diffused regions having the ends on the gate electrode sides extended up to below the gate electrodes, whereby the effective channel length of the load transistors L1, L2 and the driver transistors D1, D2 can be decreased, and drive current can be increased.

In the above, the present invention is applied to the SRAM circuit as in the second embodiment, but the present invention is applicable to a logic circuit, a CPU circuit, a peripheral circuit, etc.

As in the modification of the second embodiment shown in FIG. 20, the SRAM cell layout may be changed so that for not only the load transistors L1, L2 and the driver transistors D1, D2 but also the transfer transistors T1, T2, the pocket ion implantation is made in one direction slanted toward the source side with respect to the semiconductor substrate 10 surface, and the ion implantation of an n-type impurity can be made in one direction slanted toward the drain side with respect to the semiconductor substrate 10 surface.

### Modified Embodiments

The present invention is not limited to the above-described embodiments and can cover other various modifications.

For example, in the above-described embodiments, the pocket ion implantation is made in one direction slanted toward the source side with respect to the semiconductor substrate 10 surface but may be made in one direction slanted toward the drain side with respect to the semiconductor substrate 10 surface, depending on application, etc. of the MOS transistors. For example, for the load transistors L1, L2, the pocket ion implantation may be made in one direction slanted toward the drain side with respect to the semiconductor substrate 10 surface, which can increase the drive current of the load transistors L1, L2.

In the above-described embodiments, the pocket ion implantation for forming the pocket region is made in one direction slanted toward the source side with respect to the semiconductor substrate 10 surface, but the ion implantation for forming the LDD region may be made in one direction slanted toward the source side or the drain side with respect to the semiconductor substrate 10 surface. The ion implantation for forming the LDD region is made in one direction slanted toward the source side with respect to the semiconductor substrate 10 surface, whereby the LDD region can be formed selectively only in the source diffused layer. The LDD region is thus formed, whereby the GIDL can be decreased, and the electric power consumption of the semiconductor device in stand-by can be decreased.

In the above-described embodiments, the present invention is applied to the MOS transistor having the source/drain diffused layers of the LDD structure but is also applicable to the MIS transistor having the so-called extension source/drain structure and MIS transistors having other diffused layer structures.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device comprising:
a plurality of MIS transistors each including a gate electrode formed over a semiconductor substrate with a gate insulating film formed therebetween, and a source diffused layer and a drain diffused layer of a second conduction type formed in the semiconductor substrate on both sides of the gate electrode and arranged with a channel region of a first conduction type therebetween,
the source diffused layers and the drain diffused layers of said plural MIS transistors being arranged side by side in the same direction,
a pocket region of the first conduction type being formed selectively between the source diffused layer and the channel region of each of said plural MIS transistors, and a pocket impurity-not-implanted region being formed between the drain diffused layer and the channel region of each of said plural MIS transistors.

2. A semiconductor device according to claim 1, wherein
the drain diffused layer of each of said plural MIS transistors includes an impurity diffused region extended up to below the gate electrode.

3. A semiconductor device according to claim 1, including
a plurality of memory cells each including a first inverter having a first load transistor and a first driver transistor, a second inverter having a second load transistor and a second driver transistor, a first transfer transistor for controlling the first inverter and the second inverter, and a second transfer transistor for controlling the first inverter and the second inverter,
said plural MIS transistors comprising the first and the second load transistors.

4. A semiconductor device according to claim 3, wherein
the drain diffused layer of each of the first and the second load transistors includes an impurity diffused region extended up to below the gate electrode.

5. A semiconductor device according to claim 1, including
a plurality of memory cells each including a first inverter having a first load transistor and a first driver transistor, a second inverter having a second load transistor and a second driver transistor, a first transfer transistor for controlling the first inverter and the second inverter, and a second transfer transistor for controlling the first inverter and the second inverter,
said plural MIS transistors comprising the first and the second driver transistors.

6. A semiconductor device according to claim 5, wherein
the drain diffused layer of each of the first and the second driver transistors includes an impurity diffused region extended up to below the gate electrode.

7. A semiconductor device according to claim 1, including
a plurality of memory cells each including a first inverter having a first load transistor and a first driver transistor, a second inverter having a second load transistor and a second driver transistor, a first transfer transistor for controlling the first inverter and the second inverter, and a second transfer transistor for controlling the first inverter and the second inverter,
said plural MIS transistors comprising the first and the second transfer transistors.

8. A semiconductor device according to claim 7, wherein
the drain diffused layer of each of the first and the second transfer transistors includes an impurity diffused region extended up to below the gate electrode.

9. A method of manufacturing a semiconductor device comprising the steps of:
forming gate electrodes of a plurality of MIS transistors over a semiconductor substrate; and
forming a source diffused layer and a drain diffused layer of a second conduction type arranged with a channel region of a first conduction type therebetween in the semiconductor substrate on both sides of the gate electrode of each of said plural MIS transistors,
the source diffused layers and the drain diffused layers of said plural MIS transistors being arranged side by side in the same direction, and
the method further comprising the step of
implanting an impurity of the first conduction type in one direction slanted toward the source diffused layer with the gate electrode as a mask to thereby form a pocket region of the first conduction type selectively between the source diffused layer and the channel region of each of said plural MIS transistors.

10. A method of manufacturing a semiconductor device according to claim 9, further comprising the step of
implanting an impurity of the second conduction type in one direction slanted toward the drain diffused layer with the gate electrode as a mask to thereby form in the drain diffused layer of each of said plural MIS transistors a first impurity diffused region extended up to below the gate electrode.

11. A method of manufacturing a semiconductor device according to claim 9, wherein
the step of forming the source diffused layer and the drain diffused layer comprises the step of implanting an impurity of the second conduction type in one direction slanted toward the source diffused layer or the drain diffused layer with the gate electrode as a mask to thereby form a second impurity diffused region, and the step of forming a sidewall insulating film on a side wall of the gate electrode and then implanting an impurity of the second conduction type with the gate electrode and the sidewall insulating film as a mask to thereby form a third impurity diffused region.

12. A method of manufacturing a semiconductor device according to claim 10, wherein
the step of forming the source diffused layer and the drain diffused layer comprises the step of implanting an impurity of the second conduction type in one direction slanted toward the source diffused layer or the drain diffused layer with the gate electrode as a mask to thereby form a second impurity diffused region, and the step of forming a sidewall insulating film on a side wall of the gate electrode and then implanting an impurity of the second conduction type with the gate electrode and the sidewall insulating film as a mask to thereby form a third impurity diffused region.

13. A method of manufacturing a semiconductor device according to claim 9,
the semiconductor device including a plurality of memory cells each including a first inverter having a first load transistor and a first driver transistor, a second inverter having a second load transistor and a second driver transistor, a first transfer transistor for controlling the first inverter and the second inverter, and a second transfer transistor for controlling the first inverter and the second inverter,
said plural MIS transistors comprising the first and the second load transistors.

14. A method of manufacturing a semiconductor device according to claim 13, further comprising the step of
implanting an impurity of the same conduction type as the conduction type of the source diffused layers and the drain diffused layers of the first and the second load transistors in one direction slanted toward the drain diffused layers of the first and the second load transistors with the gate electrodes of the first and the second load transistors as a mask to thereby form in the drain diffused layer of each of the first and the second load transistors an impurity diffused region extended up to below the gate electrode.

15. A method of manufacturing a semiconductor device according to claim 9,
the semiconductor device including a plurality of memory cells each including a first inverter having a first load transistor and a first driver transistor, a second inverter having a second load transistor and a second driver transistor, a first transfer transistor for controlling the first inverter and the second inverter, and a second transfer transistor for controlling the first inverter and the second inverter,
said plural MIS transistors comprising the first and the second driver transistors.

16. A method of manufacturing a semiconductor device according to claim 15, further comprising the step of
implanting an impurity of the same conduction type as the conduction type of the source diffused layers and the drain diffused layers of the first and the second driver transistors in one direction slanted toward the drain diffused layers of the first and the second driver transistors with the gate electrodes of the first and the second driver transistors as a mask to thereby form in the drain diffused layer of each of the first and the second driver transistors an impurity diffused region extended up to below the gate electrode.

17. A method of manufacturing a semiconductor device according to claim 9,
the semiconductor device including a plurality of memory cells each including a first inverter having a first load transistor and a first driver transistor, a second inverter having a second load transistor and a second driver transistor, a first transfer transistor for controlling the first inverter and the second inverter, and a second transfer transistor for controlling the first inverter and the second inverter,
said plural MIS transistors comprising the first and the second transfer transistors.

18. A method of manufacturing a semiconductor device according to claim 17, further comprising the step of
implanting an impurity of the same conduction type as the conduction type of the source diffused layers and the drain diffused layers of the first and the second transfer transistors in one direction slanted toward the drain diffused layers of the first and the second transfer transistors with the gate electrodes of the first and the second transfer transistors as a mask to thereby form in the drain diffused layer of each of the first and the second transfer transistors an impurity diffused region extended up to below the gate electrode.
